(19) United States
(12) Patent Application Publication
(10) Pub. No.: US 2026/0164538 A1
(43) Pub. Date: Jun. 11, 2026

(54) Rail-Based Power Management Interface and Protocol

(71) Applicant: PowerLattice Technologies Inc., Camas, WA (US)

(72) Inventors: Gang Ren, Camas, WA (US); Peng Zou, Camas, WA (US); Sujith S. Dermal, Chandler, AZ (US)

(21) Appl. No.: 19/411,030

(22) Filed: Dec. 5, 2025

Related U.S. Application Data
(60) Provisional application No. 63/729,880, filed on Dec. 9, 2024.

(51) Int. Cl. H05K 1/02; H02B 1/04; H05K 1/181

(52) U.S. Cl. CPC H05K 1/0213; H02B 1/04; H05K 1/181

(57) ABSTRACT

This application is directed to power management in an electronic system that includes a plurality of power rails configured to provide a plurality of rail voltages, a plurality of power chiplets coupled to the power rails, and a power broadcast interface coupled to the power chiplets. Each power chiplet includes a plurality of voltage regulator cells (VRCs), and each respective VRC is configured to output a respective programmable rail voltage to a respective power rail. The power broadcast interface broadcasts a power control command to the plurality of power chiplets, and the power control command includes at least a rail identifier identifying a first power rail. Each of a subset of power chiplets decodes the power control command, and selects a respective set of VRCs among the plurality of respective VRCs based on the rail identifier to provide power to the first power rail.

### RELATED APPLICATION

This application claims benefit of U.S. Provisional Patent Application No. 63/729,880, titled “Apparatus of Rail Based Power Management Interface and Protocol,” filed Dec. 9, 2024, which is incorporated by reference in its entirety.

This application relates to U.S. patent application Ser. No. 19/981,154, filed Dec. 13, 2024, titled “Power Management Techniques using Location-Mapped Chiplet Configuration,” which claims benefit of U.S. Provisional Patent Application No. 63/610,347, titled “Apparatus of Configurable PMIC with Array of Micro Integrated Voltage regulator cells and Shared Programmable References,” filed Dec. 14, 2023. Each of these patent applications is incorporated by reference in its entirety.

This application also relates to U.S. application Ser. No. 18/919,345, titled “Apparatus of Configurable PMIC with Array of Micro Integrated Voltage regulator cells and Shared Programmable References,” filed Oct. 17, 2024, which claims benefit of U.S. Provisional Patent Application No. 63/592,109, titled “Apparatus of Configurable PMIC with Array of Micro Integrated Voltage regulator cells and Shared Programmable References,” filed Oct. 20, 2023. Each of these patent applications is incorporated by reference in its entirety.

This application also relates to International Patent Application No. PCT/US24/60277, titled “Power Management Techniques using Location-Mapped Chiplet Configuration,” filed Dec. 13, 2024, and International Patent Application No. PCT/US24/52093, titled “Apparatus of Configurable PMIC with Array of Micro Integrated Voltage regulator cells and Shared Programmable References,” filed Oct. 17, 2024. Each of these patent applications is incorporated by reference in its entirety.

### TECHNICAL FIELD

This application relates generally to power management of an electronic system, including, but not limited to, methods, systems, devices, and integrated circuits for configuring sets of voltage regulator cells applied in a power management integrated circuit (PMIC) that is coupled to, or included in, a system on chip (SOC).

### BACKGROUND

A system on chip (SOC) consolidates multiple components of a computer, such as a processor, memory, input/output interfaces, and various peripherals, on a substrate. SOCs are widely used in modern electronics, including smartphones, tablets, and embedded systems, where space, power efficiency, and performance are critical. To manage complex power requirements of these components, a Power Management Integrated Circuit (PMIC) is employed. The PMIC is responsible for regulating, distributing, and controlling the power delivered to the SOC's various subsystems. It efficiently manages multiple voltage levels, enabling features like dynamic voltage scaling to conserve energy and ensure the SOC operates within its optimal power and thermal limits. The SOC and PMIC form a highly efficient system capable of handling diverse tasks with minimal power consumption, making them essential in today's compact, high-performance devices. However, the PMIC applied with the SOC may face some issues with consistency among different power rails and stability within a single power rail. Consistency issues arise when different power rails fail to deliver uniform voltage levels or fail to sequence properly, leading to performance variations or even malfunctions in the SOC. This can be caused by mismatched regulation circuitry, differing load demands, or poor coordination between multiple power rails. Stability issues, on the other hand, affect individual power rails where voltage fluctuations, oscillations, or noise occur within a single rail. These problems can cause intermittent failures, timing errors, or degraded performance in the SOC.

### SUMMARY

In accordance with at least some implementations disclosed herein is at least the realization that an SOC requires consistent and reliable power delivery on its power rails. A particular challenge of driving a power rail with a set of voltage regulator cells (VRCs) is load current balancing among different VRCs (e.g., on an SOC). Each respective VRC often includes its own control loop. If each respective VRC uses a different reference voltage source (e.g., DAC), output voltages of the different VRCs can have small but substantive differences. Output reference voltages provided by two DACs based on the same code are highly unlikely to be exactly the same, causing their associated VRCs to have inconsistent output voltages and a load current imbalance. At the extreme situation of poor current balancing, a power rail driven by a set of VRCs can malfunction and get permanently damaged. As such, in accordance with at least some implementations disclosed herein is at least the realization that each power rail delivers its rail voltage consistently and that different power rails providing the same rail voltage need to be consistent with one another.

Various implementations of this application are directed to methods, systems, devices, and integrated circuits for generating one or more rail voltages to power a plurality of power rails using a configurable power management integrated circuit (PMIC), where the PMIC includes an array of micro-integrated VRCs configured to operate with location-based parameter settings. A subset of VRCs may be selected and grouped to function as a power supply driving a power rail. The PMIC may apply one or more consolidated reference circuits, and the selected VRCs associated with the power supply are driven by the same reference circuit. In some implementations, the VRCs of the PMIC are grouped to form a plurality of power supplies, e.g., each of which outputs a programmable rail voltage, and a subset of VRCs corresponding to each respective power supply is driven by a respective common reference circuit. In some embodiments, VRCs of the PMIC operate based on an encoding table including a plurality of register files corresponding to different groups of VRCs having different locations (e.g., in an SOC). Each register file defines parameter settings for individual VRCs of a respective group of VRCs based on a common location of the respective group. In some embodiments, the PMIC stores a plurality of table options corresponding to different SOC products, and the encoding table of a particular SOC product is selected from the plurality of table options.

In one aspect, an apparatus (e.g., an electronic system, an electronic device, integrated circuit) includes a first group of voltage regulator cells (VRCs) configured to operate based on parameter settings of individual VRCs, output at least one respective rail voltage, and provide the at least one respective rail voltage to one or more power rails. The apparatus includes a memory component coupled to the first group of VRCs, where the memory component stores an encoding table including a plurality of register files, and a first register file defines parameter settings for the individual VRCs of the first group of VRCs. The apparatus includes a setting interface coupled to the memory component. The setting interface is configured to receive a first parameter setting signal applied to select the first register file among the plurality of register files for defining the parameter settings for the first group of VRCs. The apparatus includes a substrate on which the first group of VRCs, the setting interface, and the memory component are integrated.

In another aspect, a method is implemented to manage power of an electronic device having a substrate, a memory component, a setting interface, and a plurality of VRCs. The method includes obtaining a first parameter setting signal via the setting interface. The method further includes, based on the first parameter setting signal, selecting a first register file from a plurality of register files of an encoding table stored on the memory component. The first register file defines parameter settings for the individual VRCs of a first group of VRCs. The method further includes identifying and setting the first group of VRCs based on the parameter settings defined by the first register file and outputting at least one respective rail voltage by the first group of VRCs to drive one or more power rails. The first group of VRCs and the settings interface are integrated on a substrate.

In some embodiments, a PMIC chip (also called power chiplet) includes a plurality of VRCs forming an array of VRCs 406. Each VRC has a respective loop control circuitry. For a particular power rail, a respective set of VRCs is grouped to supply power jointly to the particular power rail, and rail voltage setpoints associated with respective set of VRCs are adjusted in a synchronous manner. The respective set of VRCs associated with the particular power rail may be provided by the same PMIC chip. Alternatively, the respective set of VRCs associated with the particular power rail may be provided by two or more distinct PMIC chips that are synchronized with one another. In accordance with some embodiments of this application is at least a realization that it is difficult to direct voltage change commands to, and synchronize changes of rail voltages outputted by, the two or more distinct PMIC chips, while the rail voltage setpoints are sequentially addressed and programmed to the two or more distinct PMIC chips.

Some implementations of this application are directed to applying a hardware scheme to virtualize physical locations of the VRCs. In accordance with the hardware scheme, the configuration register files define associated power rails or control logic links of individual VRCs of each PMIC chip. Characteristics of each power rail are programmed using rail identifier (rail ID) based commands, which are broadcast to the plurality of PMIC chips and associated VRCs, independently of physical locations of individual PMIC chips. In some embodiments, a rail identifier is a unique number identifying a corresponding power rail in an electronic system.

In yet another aspect, a power management system includes a plurality of power rails configured to provide a plurality of rail voltages and a plurality of power chiplets (also called PMIC chips) coupled to the plurality of power rails. Each power chiplet includes a plurality of respective voltage regulator cells (VRCs), and each of the plurality of respective VRCs is configured to output a respective programmable rail voltage to a respective one of the plurality of power rails. The power management system further includes a power broadcast interface coupled to the plurality of power chiplets, and the power broadcast interface is configured to broadcast a power control command to the plurality of power chiplets and the power control command includes at least a rail identifier identifying a first power rail. Each of a subset of power chiplets is configured to decode the power control command, and select a respective set of VRCs among the plurality of respective VRCs based on the rail identifier to provide power to the first power rail.

In another aspect, an electronic device includes one or more processors powered by a plurality of rail voltages, a plurality of power rails configured to provide a plurality of rail voltages, a plurality of power chiplets coupled to the plurality of power rails, and a power broadcast interface coupled to the plurality of power chiplets. Each power chiplet includes a plurality of respective voltage regulator cells (VRCs), and each of the plurality of respective VRCs is configured to output a respective programmable rail voltage to a respective one of the plurality of power rails. The power broadcast interface is configured to broadcast a power control command to the plurality of power chiplets and the power control command includes at least a rail identifier identifying a first power rail. Each of a subset of power chiplets is configured to decode the power control command, and select a respective set of VRCs among the plurality of respective VRCs based on the rail identifier to provide power to the first power rail.

In yet another aspect, a method is implemented at a power management system including a plurality of power chiplets electrically coupled to a plurality of power rails. The method includes receiving a power control command by each of the plurality of power chiplets, and the power control command includes at least a rail identifier identifying a first power rail. The method further includes, at each of a subset of power chiplets, wherein each power chiplet includes a plurality of respective voltage regulator cells (VRCs), decoding the power control command; selecting a respective set of VRCs among the plurality of respective VRCs based on the rail identifier; and outputting, by each of the plurality of respective VRCs, a respective programmable rail voltage to a respective one of the plurality of power rails, including providing power to the first power rail via the respective set of VRCs.

These illustrative implementations are mentioned not to limit or define the disclosure, but to provide examples to aid understanding thereof. Additional implementations are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a block diagram of an example electronic system, in accordance with some implementations.

FIGS. 2A and 2B are a top perspective view and a bottom perspective view of an example electronic system including an SOC, in accordance with some implementations, respectively.

FIGS. 3A and 3B are a top perspective view and a bottom perspective view of another example electronic system, in accordance with some implementations, respectively.

FIG. 4A is a high-level block diagram of an example PMIC module, in accordance with some implementations.

FIG. 4B is a detailed block diagram of an example PMIC module, in accordance with some implementations.

FIG. 5 is a schematic diagram of an example voltage regulator cell, in accordance with some implementations.

FIG. 6A is a block diagram of an example PMIC module that applies location-mapped parameter settings based on an encoding table, in accordance with some implementations.

FIG. 6B is a detailed block diagram of an example encoding table of a PMIC module, in accordance with some implementations.

FIGS. 7A and 7B illustrate example chiplets of a PMIC module and associated location-based parameter settings, in accordance with some implementations.

FIG. 8 is a block diagram of an example electronic system including a plurality of PMIC chips (also called power chiplets), in accordance with some embodiments.

FIG. 9 is a block diagram of an example power chiplet including a programmable power array of VRCs, in accordance with some embodiments.

FIG. 10 is a block diagram of another example electronic system 1000 providing power to at least two power rails, in accordance with some embodiments.

FIG. 11 is a flow diagram of an example method for providing power to one or more power rails, in accordance with some embodiments.

Like reference numerals refer to corresponding parts throughout the several views of the drawings.

### DETAILED DESCRIPTION

Reference will now be made in detail to specific implementations, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic devices with storage capabilities.

In accordance with at least some implementations disclosed herein is the realization that an SOC requires consistent and reliable power delivery on its power rails. Each power rail delivers its rail voltage consistently, and different power rails, which are coupled to different voltage regulator cells to provide the same rail voltage, may need to be consistent with one another. Various implementations of this application are directed to methods, systems, devices, and integrated circuits for generating one or more rail voltages to power a plurality of power rails using a configurable power management integrated circuit (PMIC) that applies one or more consolidated reference circuits. The configurable PMIC includes an array of micro-integrated voltage regulator cells (VRCs). A subset of VRCs may be selected and grouped to function as a power supply driving a power rail. The selected VRCs are driven by the same reference circuit. In some implementations, the VRCs of the PMIC are grouped to form a plurality of power supplies, e.g., each of which outputs a programmable rail voltage, and a subset of VRCs corresponding to each respective power supply is driven by a respective common reference circuit.

In accordance with at least some implementations disclosed herein is the realization that a challenge of grouping a set of VRCs is load current balancing (or sharing) among the VRCs when each VRC has a respective regulation control loop. Stated another way, two VRCs provide different output voltages and experience a load current imbalance, potentially causing a power rail coupled to these two VRCs to malfunction and permanently damage electronic components powered by the power rail.

To overcome this issue, a reference circuit is shared among a set of VRCs coupled to the same power rail. An output voltage of each VRC tracks a respective reference voltage provided by the shared reference circuit. In some implementations, a digital-to-analog converter (DAC) provides a reference voltage that may drift based on varied factors (e.g., locations, manufacturing conditions), even when the DAC is programmed using fixed digital input data. When the DAC is applied within a reference voltage source driving multiple VRCs coupled to the same power rail, the reference voltage drift jointly for the VRCs coupled to the same power rail, thereby making these VRCs perform consistently and stay in balance with one another. In some implementations, an array of DACs is coupled to a reference voltage distribution bus and a switch array, and configured to provide a common voltage reference to a set of VRCs that output the same rail voltage. Each VRC does not have its self-contained DAC, thereby eliminating a current imbalance issue due to differences among self-contained DACs.

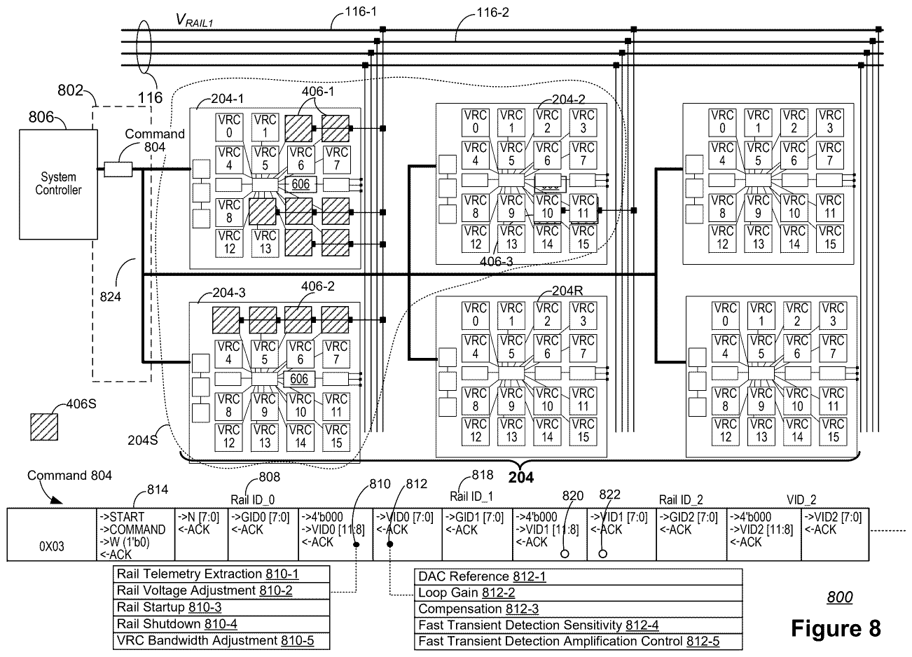

In accordance with some embodiments of this application is at least a realization that it is difficult to direct individual voltage change commands to, and synchronize changes of rail voltages V_{RAIL} outputted by, two or more distinct PMIC chips, while rail voltage setpoints are sequentially addressed and programmed to the two or more distinct PMIC chips. Some implementations of this application are directed to applying a hardware scheme to virtualize physical locations of VRCs, e.g., using local configuration register files to define associated power rails or control logic links of individual VRCs of each PMIC chip. Characteristics of each power rail are programmed using rail identifier (rail ID) based commands (e.g., power control command 804 in FIG. 8), which are broadcast to a plurality of PMIC chips including associated VRCs, e.g., independently of physical locations of individual PMIC chips and without differentiating the PMIC chips. A rail identifier (e.g., rail identifier 808) may include a unique number identifying a corresponding power rail in an electronic system. Each PMIC chip receives the rail ID based commands, identifies individual VRC(s) each having a rai ID matching that included in the rail ID based commands, and sets characteristics of the individual VRC(s) based on the rail ID based commands.

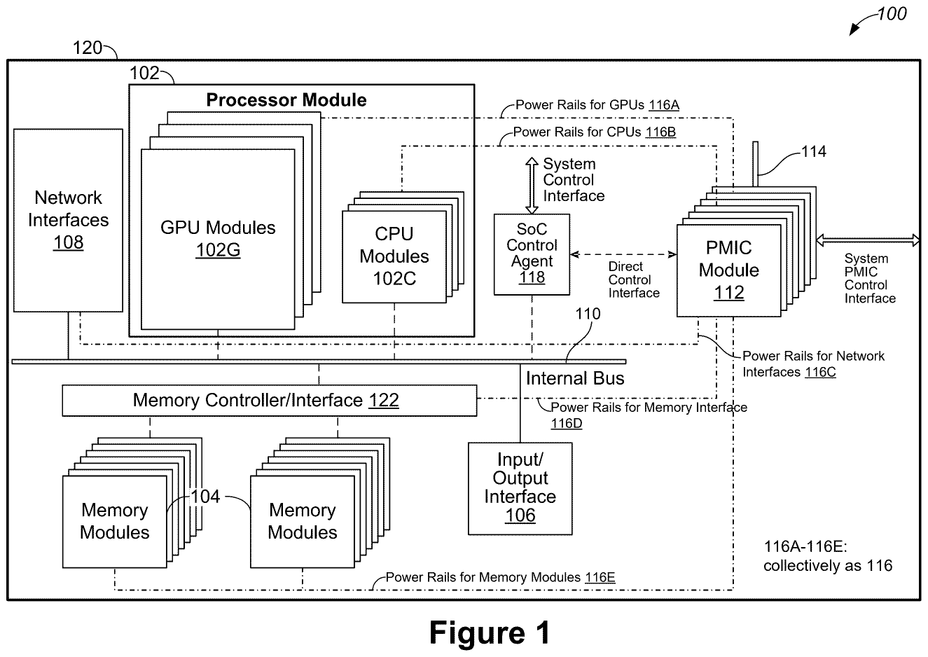

FIG. 1 is a block diagram of an example electronic system 100, in accordance with some implementations. The electronic system 100 includes at least a processor module 102, memory modules 104, an input/output (I/O) interface 106, one or more communication interfaces such as network interfaces 108, and one or more communication buses 110 for interconnecting these components. In some implementations, the I/O interface 106 allows the processor module 102 to communicate with an I/O device (e.g., a keyboard, a mouse, or a trackpad). The I/O interface 106 may comply with a data communication bus standard including, but not limited to, universal serial bus (USB) and peripheral component interconnect express (PCIe). In some implementations, the communication bus(es) 110 include circuitry (sometimes called a chipset) that interconnects and controls communications among various system components included in electronic system 100. In some implementations, the electronic system 100 further includes other specialized hardware (e.g., wireless radios, graphics card, sound card, sensors).

In some implementations, the electronic system 100 further includes a PMIC module 112 configured to receive an input supply voltage 114. The PMIC module 112 is configured to modulate the received input supply voltage 114 to desired DC voltage levels (e.g., 5 V, 3.3 V or 1.8 V) as required by various components or circuits (e.g., the processor module 102) within the electronic system 100. For example, the PMIC module 112 is configured to generate the DC voltage levels at a plurality of power rails 116 for providing power to other components (e.g., components 102-110) in the electronic system 100. Examples of the plurality of power rails 116 include, but are not limited to: one or more GPU power rails 116A, one or more CPU power rails 116B, one or more networking power rails 116C, one or more memory interface power rails 116D, and one or more memory module power rails 116E. In some implementations, the PMIC module 112 further includes a layer within a printed circuit board (PCB) or an integrated circuit (IC), and the layer is applied as an input power plane for distributing the input supply voltage 114.

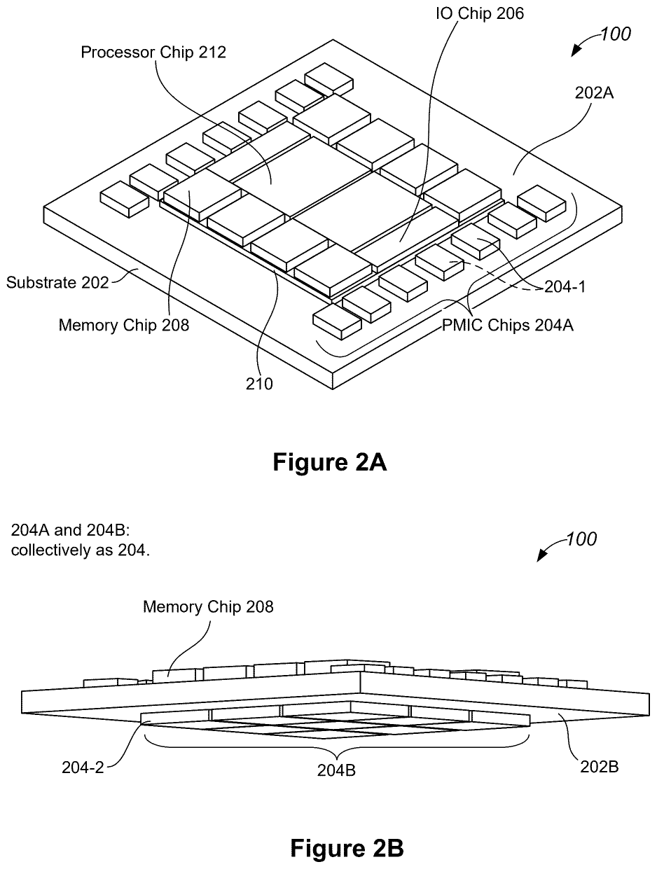

In some implementations, the electronic system 100 corresponds to an SOC 120. Different components of the electronic system 100 may be formed on two or more integrated circuits distributed on two or more chips, which are further assembled on a single substrate (e.g., substrate 202 in FIG. 2A) of the SOC 120. Alternatively, in some implementations, different components of the electronic system 100 are included in an integrated circuit formed on a single substrate of the SOC 120. In an example, the SOC 120 includes one of a silicon substrate, a polymeric substrate, a glass substrate, or a printed circuit board (PCB). Examples of the polymeric substrate include, but are not limited to, polyimide (PI), polyethylene terephthalate (PET), and polydimethylsiloxane (PDMS).

In some implementations, the SOC 120 further includes an SOC control agent 118 that refers to a control mechanism or module within the SOC 120. The SOC control agent 118 is configured to manage operation of different components (e.g., components 102-110) integrated on the SOC 120. More specifically, in some implementations, the SOC control agent 118 is configured to perform one or more of: resource management, inter-component communication, power management, task scheduling, security management, thermal management. For example, the SOC control agent 118 may allocate resources like power, processing time, and memory bandwidth to different components of the SOC 120; manages communication between various components, such as coordinating data transfers between the processor module 102 and peripherals; turn off or put certain components into a low-power state when they are not in use to conserve energy; manage scheduling of different tasks or operations across processing units of the processor module 102 within the SOC 120; implements security features (e.g., using hardware security modules, encryption, and access control); or monitor temperature sensors and adjusts operation (e.g., reducing clock speeds) to prevent overheating. In an example, the SOC control agent 118 includes one or more of: a power controller, a bus controller, and a clock controller. In some implementations, the SOC control agent 118 is implemented on a firmware level, e.g., adjusting system parameters dynamically based on workloads or external conditions.

In some implementations, the processor module 102 includes a plurality of processing units. In some implementations, the processor module 102 includes two or more different types of processing units including a subset of: one or more central processing units (CPUs) 102C, one or more graphics processing units (GPU) 102G, a digital signal processor (DSP), a neural processing unit (NPU) (also called artificial intelligence (AI) accelerator), an image signal processors (ISP), a video processing unit (VPU), an audio processing unit (APU), a secure microcontroller, and a field programmable gate array (FPGA). The CPUs 102C are configured to execute instructions from software (e.g., operating systems, applications). Examples of CPU architecture include, but are not limited to, reduced instruction set computing (RISC) and complex instruction set computing (CIS). The GPUs 102G are configured to render graphics and handle tasks that require parallel processing, such as image processing, video encoding/decoding, and machine learning.

In some implementations, the network interfaces 108 is configured to enable communication between the SOC 120 and external networks, such as local area networks (LANs) or the Internet, and includes both hardware and software components that handle data transmission, reception, and protocol management. The network interfaces 108 may include one or more interfaces for Wi-Fi, Ethernet, and Bluetooth networks, each allowing the electronic system 100 to exchange data with an external source, and participate in networked applications, such as IoT (Internet of Things), mobile communications, or cloud computing.

In some implementations, the memory modules 104 include high-speed random-access memory, such as static random-access memory (SRAM), double data rate (DDR) dynamic random-access memory (DRAM), or other random-access solid state memory devices. In some implementations, the memory modules 104 include non-volatile memory, such as one or more magnetic disk storage devices, optical disk storage devices, flash memory devices, or other non-volatile solid state storage devices. In some implementations, the memory modules 104, or alternatively the non-volatile memory device(s) within the memory modules 104, include a non-transitory computer readable storage medium. In an example, a memory module 104 includes a high bandwidth memory (HBM) configured to provide a data bandwidth greater than a bandwidth threshold to support GPUs 102G. The HBM includes a plurality of memory dies that are stacked vertically on top of each other. In some implementations, the electronic system 100 further includes a memory controller 122 coupled to manage memory access requests for the memory modules 104.

FIGS. 2A and 2B are a top perspective view and a bottom perspective view of an example electronic system 100, in accordance with some implementations, respectively. The electronic system 100 includes an SOC 120 having a substrate 202. The substrate 202 includes a first surface 202A and a second surface 202B that is opposite to the first surface 202A. The substrate 202 may be one of a silicon substrate, a polymeric substrate, a glass substrate, or a PCB. Examples of the polymeric substrate include, but are not limited to, PI, PET, and PDMS. In some implementations, each electronic component of the electronic system 100 corresponds to a region of the substrate 202, and includes a portion of an integrated circuit of the SOC 120. Alternatively, in some implementations, each electronic component of the electronic system 100 includes one or more chips that are mounted onto the substrate 202, e.g., with or without an intermediate support structure 210. In an example, the substrate 202 is made of a polymeric material, and the intermediate support structure 210 is made of silicon and applied to mechanically support a plurality of components (e.g., including an IO chip 206, a memory chip 208, a processor chip 212).

In some implementations not shown, all electronic components included in the electronic system 100 are disposed on the first surface 202A of the substrate 202. Alternatively, in some implementations, a first subset of electronic components of the electronic system 100 are disposed on the first substrate 202A of the substrate 202, and a second subset of electronic components of the electronic system 100 are disposed on the second substrate 202B of the substrate 202. In an example, one or more chips corresponding to a subset of the electronic components 102-108, 118, and 122 are disposed on the second surface 202B. In another example, one or more chips corresponding to the PMIC module 112 are disposed on the second surface 202B.

In some implementations, the PMIC module 112 includes a plurality of distinct PMIC chips 204, which further include a first set of PMIC chips 204A and a second set of PMIC chips 204B. The first set of PMIC chips 204A are disposed on the first surface 202A of the substrate 202, e.g., jointly with all or a subset of remainder components of the SOC 120 distinct from the PMIC module 112. The second set of PMIC chips 204B are disposed on the second surface 202B of the substrate 202. A rail voltage outputted by the first set of PMIC chips 204A is routed on or under the first surface 202A, e.g., by way of a configurable power plane, to access a power rail 116 of the remainder components of the SOC 120. In some implementations, a rail voltage is outputted by the second set of PMIC chips 204B and routed vertically across the substrate 202, from the second surface 202B to the first surface 202A, to access an associated power rail 116 located on or under the first surface 202A, e.g., by way of a configurable power plane.

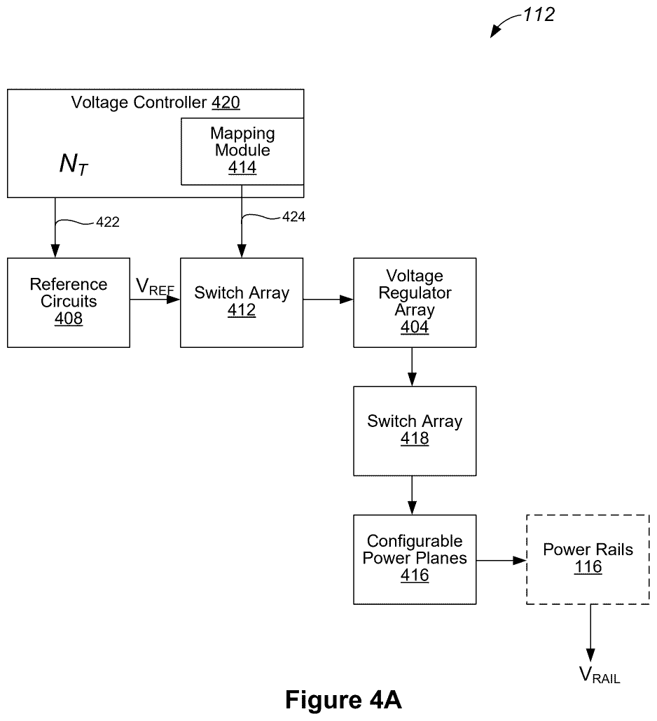

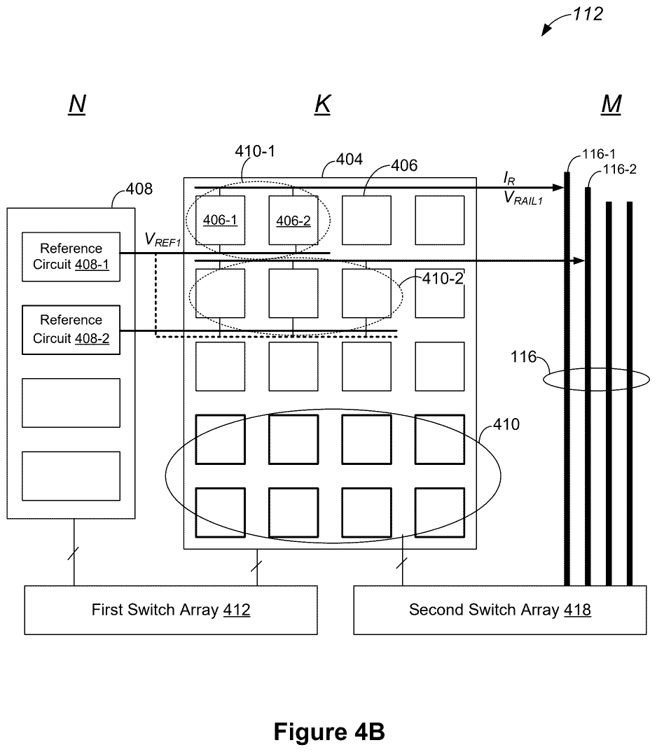

In some implementations, the PMIC module 112 includes a plurality of VRCs (e.g., VRCs 406 in FIG. 4B). In an example, a first PMIC chip 204-1 includes a subset of one or more respective VRCs (e.g., VRCs 406 in FIG. 4B), and is disposed immediately adjacent to an IO chip 206 including the I/O interface 106, allowing the I/O interface 106 to access a rail voltage provided by the subset of VRCs of the first PMIC chip 204-1. Alternatively, in some situations, two or more first PMIC chip 204-1 are disposed immediately adjacent to the IO chip 206 to provide the rail voltage to the IO chip 206 jointly. In another example, a memory chip 208 including one of the memory modules 104 is disposed on a location of the first surface 202A, and a second PMIC chip 204-2 is disposed a location of the second surface 202B aligned with (e.g., opposite to) the location of the first surface 202A. The second PMIC chip 204-2 includes a subset of one or more respective VRCs (e.g., VRCs 406 in FIG. 4B), and allows the one of the memory modules 104 to access a rail voltage provided by the respective VRCs vertically. By these means, a component of the SOC 120 may access its associated VRC(s) located on a respective PMIC chip 204 that is disposed in proximity to the component without introducing an extended length to access a power rail 116, which helps reduce resistive and capacitive parasitics of the power rail 116 and enhance performance of the SOC 120.

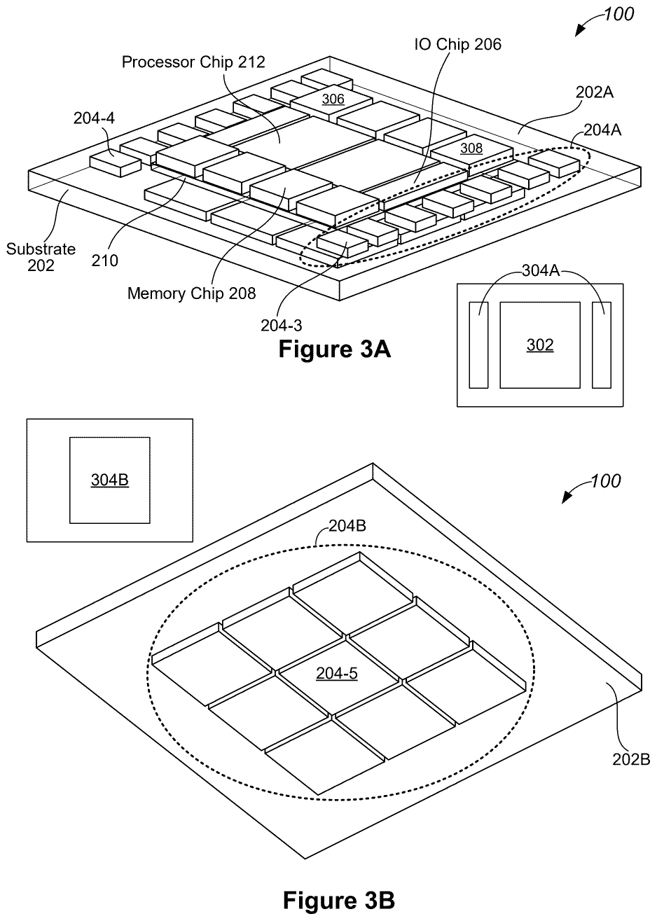

FIGS. 3A and 3B are a top perspective view and a bottom perspective view of another example electronic system 100, in accordance with some implementations, respectively. In some implementations, the first surface 202A of the substrate 202 includes a device region 302 on which a plurality of component chips (e.g., processor chip 212, IO chip 206, memory chips 208) are disposed. One or more first PMIC regions 304A (e.g., two PMIC regions) are located adjacent to the device region 302, and a first set of PMIC chips 204A are disposed on the one or more PMIC regions 304A of the first surface 202A of the substrate 202. For example, two rows of PMIC chips 204A are disposed adjacent to two opposing sides of the device region 302. In another example not shown, four rows of PMIC chips 204A are disposed adjacent to four distinct sides of the device region 302, respectively.

In some implementations not shown, the second surface 202B of the substrate 202 includes an alternative device region on which one or more component chips (e.g., processor chip 212, IO chip 206, memory chips 208) are disposed and one or more PMIC regions on which a second set of PMIC chips 204B are disposed, independently of a chip arrangement of the first surface 202A. Alternatively, in some implementations (FIG. 3B), the second surface 202B of the substrate 202 includes a second PMIC region 304B. Referring to FIG. 3A, the perspective view of the integrated electronic system 100 is depicted from the top angle with a see-through effect (e.g., to see through the substrate 202). In some implementations, the second PMIC region 304B at least partially overlaps the device region 302, allowing a component chip mounted on the device region 302 to access an output of the second PMIC region 304B using a via (e.g., a through silicon via (TSV)).

In some implementations, centers of the second PMIC region 304B and the device region 302 are aligned with one another, i.e., a center of the second PMIC region 304B and a center of the device region 302 are directly opposite to one another on two opposing surfaces 202A and 202B of the substrate 202. Further, in some implementations, sizes of the second PMIC region 304B and the device region 302 are equal to each other. Alternatively, in some implementations, the sizes of the second PMIC region 304B and the device region 302 are different from each other. Alternatively, in some implementations, the second PMIC region 304B and the device region 302 are independent from one another in size and/or in position.

In other words, the PMIC module 112 includes a plurality of VRCs distributed in a subset of the plurality of PMIC chips 204. Each PMIC chip 204 is located at a respective position on the first surface 202A or the second surface 202B of the substrate 202. In some implementations, the plurality of VRCs is grouped based on their locations to provide a plurality of rail voltages to a plurality of power rails 116 coupled to different components of the SOC 120. More specifically, in some implementations, each power rail 116 coupled to a component (e.g., CPU chip, GPU chip, memory chip, IO chip) is coupled to a set of VRCs, which are selected based on their locations with respect to a location of the component. For example, the set of VRCs are the closest to the respective component in distance compared with a remainder of the VRCs, thereby controlling associated resistive and capacitive parasitics. In another example, the set of VRCs, which coupled to the respective component, provides the lowest parasitic level. Among two VRCs having equal distances from the respective component, a VRC located on the first surface 202A is selected over a VRC located on the second surface 202B. In some implementations, a VRC located on the first surface 202A and having a larger distance from the respective component is selected over a VRC located on the second surface 202B and having a smaller distance from the respective component.

In some implementations, the PMIC module 112 further includes a plurality of reference circuits (e.g., circuit 400 in FIGS. 4A and 4B). The plurality of reference circuits may be formed on the same PMIC chip 204 or distributed on two or more PMIC chips 204. For example, each PMIC region 304A or 304B includes at least one PMIC chip 204 (e.g., chips 204-3, 204-4, and 204-5) dedicated to providing one or more reference circuits. In another example, all of the plurality of reference circuits used within the VRCs of the PMIC module 112 are consolidated on a single PMIC chip (e.g., chip 204-5).

Alternatively, in some implementations, the plurality of reference circuits used with the VRCs of the PMIC module 112 are provided by a single chip 306 or distributed among a plurality of chips (e.g., chips 306 and 308), which are mounted on, or integrated in, the device region 302.

FIG. 4A is a high-level block diagram of an example PMIC module 112, in accordance with some implementations, and FIG. 4B is a detailed block diagram of an example PMIC module 112, in accordance with some implementations. The PMIC module 112 includes, or is coupled to, a plurality of power rails 116 configured to provide one or more rail voltages V_{RAIL}. The PMIC module 112 further includes an array 404 of VRCs 406 and a plurality of reference circuits 408. The plurality of reference circuits 408 are coupled to, but distinct from, the array 404 of VRCs 406. The array 404 of VRCs 406 is coupled to the plurality of power rails 116, and configured to provide a plurality of voltage regulator sets 410. Each voltage regulator set 410 is configured to output a respective rail voltage V_{RAIL} to a respective power rail 116. Each of the plurality of reference circuits 408 is shared by, and configured to provide a respective reference voltage V_{REF} to, one or more respective VRCs 406 of a respective voltage regulator set 410. The respective voltage regulator set 410 is configured to generate the respective rail voltage V_{RAIL} based on the respective reference voltage V_{REF}.

Stated another way, some implementations of this application include a PMIC module 112 that has an array 404 of VRCs 406, a plurality of voltage references 408 that are selectable and programmable, and distribution circuits and buses that are selectable. Different numbers of VRCs 406 may be grouped together to form a voltage regulator set 410 for outputting a rail voltage V_{RAIL} (also called a power supply voltage). The array 404 of VRCs 406 may be grouped to form a single voltage regulator set 410 or a plurality of voltage regulator sets 410, thereby providing a single rail voltage V_{RAIL} or multiple rail voltages V_{RAIL}. In some implementations, the PMIC module 112 provides a plurality of rail voltages V_{RAIL} correspond to a plurality of distinct voltage regulator sets 410, and each voltage regulator set 410 includes a respective number of VRCs 406, independently of other voltage regulator set(s) 410. For each voltage regulator set 410, outputs of the respective VRCs 406 are electrically coupled (e.g., shortened) to one another and further to a respective power rail 116. In some implementations, a voltage regulator set 410 is configured to output a variable rail voltage V_{RAIL}, e.g., to track a respective reference voltage V_{REF}.

In some implementations, the PMIC module 112 includes, or is coupled to, a single substrate (e.g., substrate 202 in FIGS. 2A and 2B). The array 404 of VRCs 406 and the plurality of reference circuits 408 are disposed on the substrate 202, separately from one another. In some implementations, the array 404 of VRCs 406 and the plurality of reference circuits 408 correspond to different sets of PMIC chips 204 disposed on PMIC regions 304A and 304B (FIGS. 3A and 3B) of the substrate 202. Alternatively, in some implementations, the array 404 of VRCs 406 is distributed in PMIC chips 204 disposed on the PMIC regions 304A and 304B of the substrate 202, and the plurality of reference circuits 408 correspond to chips (e.g., chip 306 or 308 in FIG. 3A) disposed on a device region 302 (FIG. 3A) of the substrate 202.

Referring to FIG. 4B, in some implementations, the plurality of power rails 116 include a first number M of power rails 116, and the plurality of reference circuits 408 include a second number N of reference circuits 408. The second number N is equal to or less than the first number M. Further, in some implementations, each reference circuit 408 and a respective power rail 116 is uniquely associated with each other, and the respective reference circuit 408 is configured to provide the respective reference voltage V_{REF} to the respective VRC set 410 assigned to generate the rail voltage V_{RAIL} for the power rail 116. A number of VRCs 406 in the respective VRC set 410 may be varied.

In some implementations, rail voltages V_{RAIL} of two power rails 116-1 and 116-2 are equal to each other, and each power rail 116 maintains a consistent voltage. It is required that VRCs 406 contributing to each respective power rail 116-1 or 116-2 be driven by the same respective reference circuit 408. Further, in some implementations, two voltage regulator sets 410-1 and 410-2 corresponding to the two power rails 116-1 and 116-2 are coupled to two distinct reference circuits 408-1 and 408-2. Alternatively, in some implementations, the two voltage regulator sets 410-1 and 410-2 corresponding to the two power rails 116-1 and 116-2 are coupled to the same reference circuit 408 (e.g., 408-1). As such, the second number N of the reference circuits 408 is equal to or less than the first number M of the power rails 116.

In some implementations, the plurality of power rails 116 include a first number M of power rails 116, and the plurality of reference circuits 408 include a second number N of reference circuits 408. The array 404 of VRCs 406 includes a third number K of VRCs 406. The second number N is equal to or less than (≤) the third number K, and the first number M is equal to or less than (≤) the third number K.

In some implementations, the PMIC module 112 includes a first switch array 412 (e.g., having the second number N of rows and the third number K of columns, or the second number N of columns and the third number K of rows). For example, rows of the first switch array 412 are electrically coupled to the second number N of reference circuits 408, and columns of the first switch array 412 are electrically coupled to the third number K of VRCs 406 of the array 404. Each row-column cross section of the first switch array 412 includes a switch component configured to control coupling of a respective reference circuit 408 and a respective VRC 406. For each voltage regulator set 410 (e.g., set 410-1 in FIG. 4B), a respective set of switch components of the first switch array 412 are enabled to couple the respective reference circuit 408 (e.g., circuit 408-1) to the one or more respective VRCs 406 (e.g., VRCs 406-1 and 406-2). Note that, in some implementations, lines connecting the reference circuits 408-1 and 408-2 directly to the VRCs 406 in the voltage regulator sets 410-1 and 410-2 may not correspond to interconnects and are drawn in FIG. 4B merely for illustrative purposes.

Referring back to FIG. 4A, in some implementations, the PMIC module 112 further includes a mapping module 414 coupled to the first switch array 412. The mapping module 414 is configured to control the switch components of the first switch array 412 to group the VRCs 406 to form the plurality of voltage regulator sets 410. More specifically, the mapping module 414 is configured to determine whether to enable or disable each of the switch components of the first switch array 412.

In some implementations, the PMIC module 112 further includes a plurality of configurable power planes 416 embedded in a module substrate of the PMIC module 112 or a substrate 202 to which the PMIC module 112 is mounted. Each of the plurality of power rails 116 is electrically coupled to a respective power plane 416, and extends to one or more electrical components (e.g., modules 102-108) to provide a respective rail voltage V_{RAIL} to these components. Each output of VRCs 406 of a respective voltage regulator set 410 is also electrically coupled to the respective power plane 416, providing the power voltage V_{RAIL} to the respective power plane 416.

Further, referring to FIG. 4B, in some implementations, the PMIC module 112 includes a second switch array 418 (e.g., having the first number M of rows and the third number K of columns, or the first number M of columns and the third number K of rows). For example, rows of the first switch array 412 are electrically coupled to the first number M of power rails 116 or configurable power planes 416, and columns of the second switch array 418 are electrically coupled to outputs of the third number K of VRCs 406 of the array 404. Each row-column cross section of the second switch array 418 includes a switch component configured to control coupling a respective VRC 406 to a respective configurable power plane 416 or to a respective power rail 116. For each voltage regulator set 410 (e.g., set 410-1 in FIG. 4B), a respective set of switch components of the first switch array 412 are enabled to couple the one or more respective VRCs 406 (e.g., VRCs 406-1 and 406-2) to the a respective configurable power plane 416 or to the respective power rail 116 (e.g., rail 116-1). Additionally, in some implementations, the second switch array 418 and the first switch array 412 are integrated in a single switch array.

Note that, in some implementations, lines connecting the power rails 116-1 and 116-2 directly to the VRCs 406 in the voltage regulator sets 410-1 and 410-2 may not correspond to interconnects and are drawn in FIG. 4B merely for illustrative purposes.

In some implementations, the plurality of voltage regulator sets 410 include a first voltage regulator set 410-1 that is configured to output a first rail voltage V_{RAIL1} (e.g., 1.2V, 0.8V) to a first power rail 116-1, and the first rail voltage is equal to a first reference voltage V_{REF1} provided by a first reference circuit 408-1. Stated another way, an output voltage level of each voltage regulator set 410 is set by its associated reference voltage, and the voltage regulator set 410 is configured to track its associated reference voltage provided by a respective reference circuit 408.

Referring back to FIG. 4A, in some implementations, the PMIC module 112 further includes a voltage controller 420 coupled to the plurality of reference circuits 408. The voltage controller 420 is configured to generate a digital control signal 422 based on the first rail voltage associated with the first power rail 116-1 and provide the digital control signal 422 to the first reference circuit 408-1 defining the first reference voltage V_{REF1}. The first power rail 116-1 extends to one or more electrical components (e.g., modules 102-108) to provide the first rail voltage to these components. Characteristics of the first power rail 116-1 (e.g., rail current, rail voltage) are determined based on operation of the one or more electrical components. The first reference voltage of the first reference circuit 408-1 is further determined and set based on the characteristics of the first power rail 116-1. In some implementations, the plurality of reference circuits 408 are identical to one another. The digital control signal 422 determines magnitudes of the reference voltages V_{REF} outputted by the plurality of reference circuits 408. Conversely, in some implementations, at least two of the plurality of reference circuits 408 are different from one another. In an example, each reference circuit 408 includes a digital-to-analog converter (DAC).

Additionally, in some implementations, the first voltage regulator set 410-1 further includes a target number N_{T} (e.g., 2) of VRCs 406 and is configured to deliver up to a predefined rail current I_{RAIL} to the first power rail 116-1. The target number N_{T} is determined based on the predefined rail current I_{RAIL}, e.g., equal to the predefined rail current I_{RAIL} divided by a regulator current I_{VGC} that is deliverable by each VRC 406. Additionally, in some implementations, the PMIC module 112 further includes a voltage controller 420 coupled to the array 404 of VRCs 406. The voltage controller 420 is configured to determine the target number N_{T} based on the predefined rail current I_{RAIL} associated with the first power rail 116-1, generate one or more select signals 424 based on the target number N_{T}, and provide the one or more select signals 424 to the array 404 of VRCs 406 to select the target number N_{T} of VRCs 406 (e.g., VRCs 406-1 and 406-2) of the first voltage regulator set 410-1. In some implementations, the mapping module 414 is part of the voltage controller 420.

In some implementations, VRCs 406 in the array 404 of VRCs 406 are identical to each other. An output voltage of each VRC 406 is determined based on a respective reference voltage V_{REF} received by the respective VRC 406. The higher a rail current I_{RAIL} of a power rail 116, the larger the target number N_{T} of the VRCs 406 grouped to drive the power rail 116.

Conversely, in some implementations, at least two VRCs 406 in the array 404 of VRCs 406 are different from one another. For example, an output voltage of each VRC 406 is determined based on a respective reference voltage V_{REF} received by the respective VRC 406. The two VRCs 406 may have different driving capabilities (e.g., different regulator currents). Different numbers of the two VRCs 406 may be selected and combined based on a rail current I_{RAIL} associated with a power rail 116 and regulator currents I_{VGC} of the two VRCs 406.

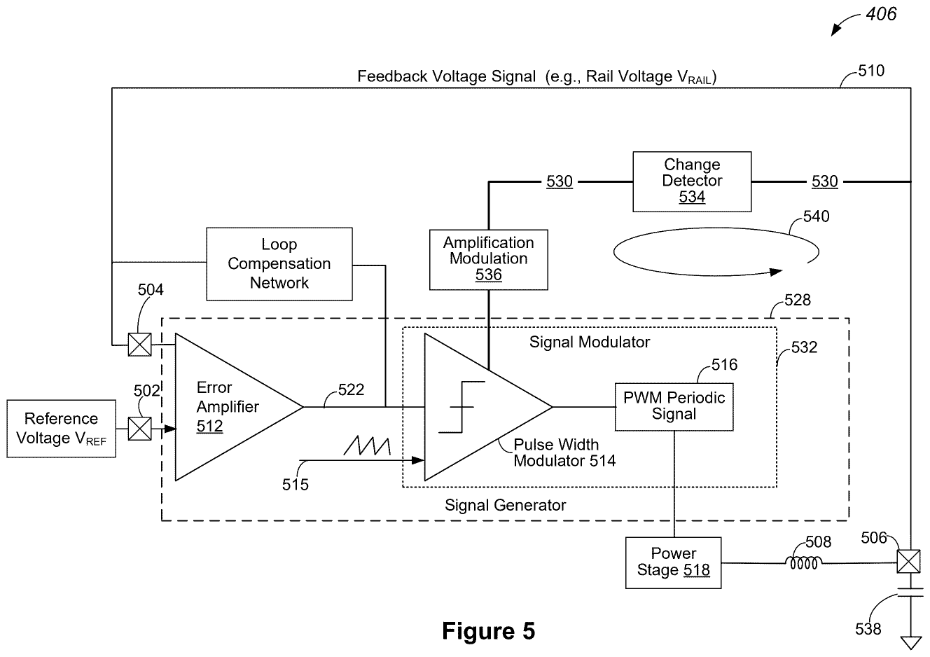

FIG. 5 is a schematic diagram of an example VRC 406, in accordance with some implementations. In some implementations, the VRC 406 includes an input reference interface 502 for receiving a target reference voltage V_{REF}, an input signal interface 504 for receiving an input signal (e.g., rail voltage V_{RAIL}), an output interface 506 for providing a rail voltage V_{RAIL} to a power rail (e.g., power rail 116-1 in FIG. 4B), a first feedback path 510 coupling the output interface 506 of the VRC 406 to the input signal interface 504 of the VRC 406, and an inductor 508 electrically coupled between the input signal interface 504 and the output interface 506.

In some implementations, the VRC 406 includes an error amplifier 512, a pulse width modulator 514, a power stage 518, and the feedback path 510. The error amplifier 512 is configured to receive a reference voltage V_{REF} and a rail voltage V_{RAIL} and generate an amplified difference signal 522. The pulse width modulator 514 is coupled to the error amplifier 512 configured to generate a pulse width modulated (PWM) periodic signal 516 having a pulse width and a feature frequency f. In an example, the pulse width modulator 514 includes a comparator, and receives an input signal 515 having a Sawtooth waveform or a triangular waveform. The pulse width modulator 514 is coupled to the error amplifier 512 and configured to modulate the pulse width of the input signal 515. The power stage 518 is coupled to the pulse width modulator 514 and configured to generate the rail voltage V_{RAIL} based on the PWM periodic signal 516. In an example, the power stage 518 includes one or more power field effect transistors (FETs). The feedback path 510 is configured to couple an output of the power stage 518 to an input of the error amplifier 512, e.g., jointly with an inductor 508.

In some implementations, the VRC 406 includes a signal generator 528, a power stage 518, and a first feedback path 510 coupling an output of the power stage to a signal input of the signal generator 528. The signal generator 528 is configured to receive a target reference voltage V_{REF} and a rail voltage V_{RAIL} and generate a PWM periodic signal 516 having a target pulse width. The power stage 518 is coupled to the signal generator 528 and configured to generate the rail voltage based on the PWM periodic signal 516 having the target pulse width. Further, in some implementations, in the VRC 406, a second feedback path 530 couples the output of the power stage 518 to a signal modulator 532 of the signal generator 528. The second feedback path 530 is configured to pull the rail voltage V_{RAIL} back to the target reference voltage V_{REF} when the rail voltage V_{RAIL} deviates from the target reference voltage V_{REF} at a deviation rate higher than a characteristic circuit rate of the VRC 406.

Further, in some implementations, the second feedback path 530 further includes a change detector 534 and an amplification and modulation circuit 536. The change detector 534 is coupled to the output of the power stage 518, and configured to detect the rail voltage V_{RAIL} deviating from the target reference voltage V_{REF} at the deviation rate. The amplification and modulation circuit 536 is coupled to the change detector 534 and the signal modulator 532, and configured to adjust a pulse width of the PWM periodic signal 516 in real-time, when the rail voltage V_{RAIL} deviates from the target reference voltage V_{REF} at the deviation rate. In other words, in some implementations, the change detector 534 is configured to sense fast voltage changes in the feedback voltage signal in the first feedback path 510 (e.g., corresponding to fast voltage changes in an output of the VRC 406). The change detector 534 generates a modulation signal to modulate the signal modulator 532, thereby preventing an output of the VRC 406 from deviating from the reference voltage V_{REF}.

State another way, in some implementations, the VRC 406 is implemented based on a regulation control loop using one or more of a power stage 518, an integrated on-chip inductor 508, and a feedback voltage signal (e.g., carrying rail voltage V_{RAIL} in a first feedback path 510). The regulation control loop tracks a difference between voltage feedback signal and the selected reference voltage V_{REF}, and generates pulse width modulated signals (e.g., PWM periodic signal 516) driving the power stage 518. The output of the power stage 518 may drive an integrated on-chip inductor 508.

In some implementations, an inductor 508 and an output filter capacitor 538 forms an output filter. The output filter may be part of, or external to, a respective VRC 406. The output filter may partially belong to a respective VRC 406. The output filter capacitor 538 may be embedded in a GPU or CPU package substrate, a substrate of the SOC 120 (e.g., substrate 202), or a processor chip 212 (FIG. 2A). In some implementations, for a voltage regulator set 410, output terminals of on-chip inductors 508 of VRCs 406 of the voltage regulator set 410 correspond to the output interface 506, and are coupled via interconnects to an output filter capacitor 538, which may be external to the VRCs 406. Stated another way, the VRCs 406 of the voltage regulator set 410 share, and is routed separately via the interconnects to, a common output filter capacitor 538. Further, in some implementations, the feedback voltage signal carried by the feedback path 510 is connected to the output filter capacitor via the interconnects extending external to the VRCs 406.

Additionally, in some implementations, a regulation control mechanism of a VRC 406 employs dual control loops including the regulation control loop and a transient modulation loop 540. The regulation control loop is based on the first feedback path 510, and configured to modulate the PWM periodic signal 516 based on an error signal (e.g., amplified difference signal 522) generated by integrating a difference between the reference voltage V_{REF} and the feedback voltage signal. In some implementations, the regulation control loop integrates a difference between the reference voltage V_{REF} and the feedback voltage signal, and includes a signal modulator 532, which is shared with the transient modulation loop 540. The amplified difference signal 522 reflects integration of the difference between the reference voltage V_{REF} and the feedback voltage signal, and is applied to modulate the PWM periodic signal 516 and generate a rail voltage V_{RAIL} to be outputted at the output interface 506 of the VRC 406. The rail voltage V_{RAIL} settles at the associated reference voltage V_{REF}. Additionally, the transient modulation loop 540 is configured to modulate the PWM periodic signal 516 based on detection of transient characteristics of the feedback voltage signal (e.g., the rail voltage V_{RAIL}).

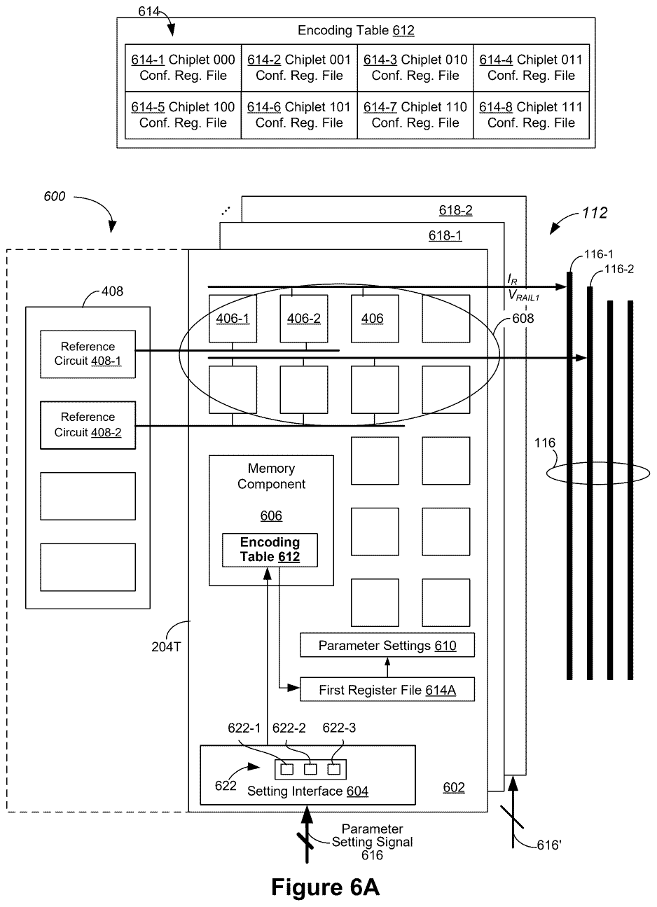

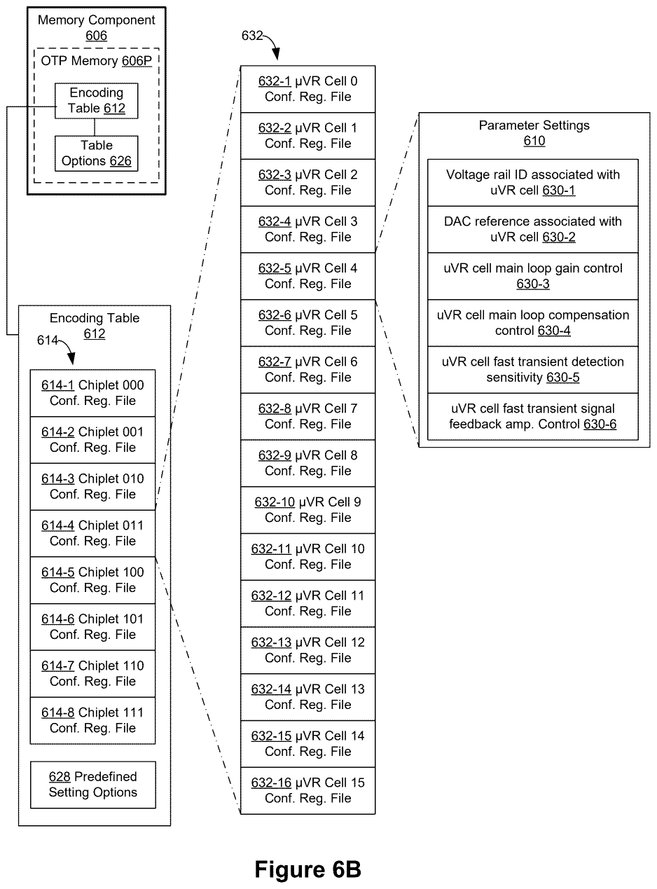

FIG. 6A is a detailed block diagram of an example electronic device 600 that includes a PMIC module 112 implementing location-mapped parameter settings 610, in accordance with some implementations. The PMIC module 112 includes some or all of the components of the PMIC module 112 described with respect to FIGS. 4A and 4B. In some embodiments, the PMIC module 112 includes a plurality of PMIC chips 204 (e.g., chips 204-1, 204A, and 204B in FIGS. 2A and 2B). A plurality of VRCs 406 are distributed on the plurality of PMIC chips 204, and each of a subset of PMIC chips 204 includes a group of respective VRCs 406. For example, the substrate 602 corresponds to one of the plurality of PMIC chips 204 (e.g., a PMIC chiplet 204T) of the PMIC module 112, and The PMIC chiplet 204T includes at least a first group 608 of VRCs 406 and a setting interface 604, which are integrated on the substrate 602. A memory component 606 may be coupled to, or included in, the PMIC chiplet 204T. The first group 608 of VRCs 406 may include less than all VRCs 406 or all VRCs 406 of the PMIC chiplet 204T. In some embodiments, the first group 608 of VRCs 406 provide the voltage regulator set 410-1 (FIG. 4B) for driving a first power rail 116-1.

The first group 608 of VRCs 406 is configured to operate based on parameter settings 610 of individual VRCs 406 within the first group 608 of VRCs 406. Based on the parameter settings 610, the first group 608 of VRCs 406 is configured to output at least one respective rail voltage, and provide the at least one respective rail voltage to one or more power rails 116 (e.g., the power rail 116-1, the power rail 116-2, etc.). In some embodiments, the substrate 602 corresponds to a PMIC chip 204T, and is part of an SOC (e.g., a PMIC of the SOC).

In some embodiments, the memory component 606 stores an encoding table 612 that includes a plurality of register files 614 (e.g., a register file 614-1, a register file 614-2, etc.), where a first register file 614A (e.g., the register file 614-1) of the plurality of register files 614 defines parameter settings 610 for the individual VRCs of the first group 608 of VRCs 406. In some embodiments, the memory component 606 includes a memory chip 208 distinct from the substrate 602 of the PMIC chip 204T and the PMIC chip 204T obtains the encoding table 612 from the memory chip 208, which may provide the encoding table 612 to two or more PMIC chips 204. Alternatively, in some embodiments, each of a subset of PMIC chips 204 has a group of respective VRCs 406, and includes a distinct memory component 606 locally on a respective substrate 602.

In some embodiments, the setting interface 604 is coupled to the memory component 606 (e.g., physically coupled, communicatively coupled, etc.). The setting interface 604 is configured to receive a first parameter setting signal 616 applied to select the first register file 614A (e.g., a configuration register file 614-4) among the plurality of register files for defining the parameter settings 610 for the voltage regulator set 410-1. In some embodiments, the PMIC chiplet 204T is part of an SOC. The setting interface 604 is electrically coupled to (e.g., mate) a set of SOC pins (not shown) located on a substrate of the SOC, and configured to receive a first parameter setting signal 616 from the set of SOC pins. The set of SOC pins are electrically coupled based on a relative location in the SOC, thereby making the first parameter setting signal 616 depend on the relative location of the SOC pins (e.g., a location of the PMIC chiplet 204T) in the SOC.

In some implementations, the settings interface 604 includes a plurality of pins (e.g., a set of pins 622-1-622-3), and the first parameter setting provided by the parameter setting signal 616 includes a set of hardwired pin values, which are received via the plurality of pins and applied to select the first register file 614A for defining the parameter settings 610 for the first group 608 of VRCs 406 (e.g., one or more of the pins 622). In some implementations, the at least one respective rail voltage includes a first rail voltage (e.g., 5 V, 3.3 V or 1.8 V) provided by a first subset of VRCs in the first group 608 of VRCs 406, and output pins of the first subset of VRCs are electrically coupled to one another and to a first power rail 116-1.

The electronic device 600 includes a plurality of voltage references 408 configured to provide one or more reference voltages (e.g., a first reference voltage provided by the reference circuit 408-1) to the first group 608 of VRCs 406. The electronic device 600 also includes distribution circuitry including a plurality of switch components (e.g., first switch array 412 and second switch array 418 in FIG. 4B). In some implementations, the electronic device 600 includes a bus that is configured to communicatively couple the first group 608 of VRCs 406 (e.g., voltage regulator set 410-1) with a corresponding set of voltage references and a subset of distribution circuitry (e.g., first switch array 412 in FIG. 4B). In some embodiments, the plurality of voltage references 408 are provided by the same substrate 602 of the PMIC chiplet 204T including the first group 608 of VRCs 406. In some embodiments not shown, the plurality of voltage references 408 are provided by a substrate (e.g., substrate 618-1, 618-2) of a PMIC chiplet distinct from the PMIC chiplet 204T. In some embodiments not shown, the plurality of voltage references 408 are provided by a substrate of a PMIC chiplet that is dedicated to voltage referencing. In some embodiments not shown, the plurality of voltage references 408 are distributed among a plurality of PMIC chips 204 that may or may not include the PMIC chiplet 204T.

In some implementation, the first group 608 of VRCs 406 is included in one of a plurality of individual chiplets, and each respective chiplet of the plurality of individual chiplets is electrically coupled to a same reference voltage. For example, VRCs 406-1 and 406-2 may be part of a first chiplet, and each of the respective VRCs may be coupled to the reference circuit 408-1 providing a same reference voltage.

In some implementations, the substrate 602 includes a first substrate of a plurality of substrates, and the plurality of substrates includes one or more second substrates (e.g., substrates 618-1 and 618-2). In some implementations, each respective second substrate of the plurality of substrates is associated with a respective set of pin values (e.g., pin values associated with the set of pins 622) that are received via a respective parameter setting signal 616′ and applied to select a respective second register file in the encoding table 612 for defining respective parameter settings 610 for respective VRCs formed on the respective second substrate.

In some implementations, the parameter setting signal 616 corresponds to a location of the substrate 602 with respect to the electronic device 600 (e.g., a processor circuit), to which the substrate 602 is coupled or included, and is applied to select a particular register file based on the location of the substrate 602. In some implementations, the plurality of register files 614 and associated parameter settings correspond to a plurality of predefined locations for receiving the substrate 602 in the electronic device 600 (e.g., an SOC), and the parameter settings 610 defined for the individual VRCs of the first group 608 of VRCs 406 match on one of the plurality of predefined locations where the substrate 602 is disposed. In some embodiments, three distinct substrates 602, 618-1, and 618-2 have different chip locations in the electronic device 600, e.g., with reference to a processor module 102 powered by the PMIC module 112 (FIG. 1). Based on the chip locations, the register files 614-1, 614-2, and 614-3 are selected and applied to provide the parameter settings to the VRCs 406 formed on the substrates 602, 618-1, and 618-2, respectively.

FIG. 6B is a block diagram of an example encoding table 612 of a PMIC module (e.g., PMIC module 112), in accordance with some implementations. In some embodiments, the memory component 606 stores a plurality of table options 626 including the encoding table 612. The table options 626 may be applied to different types of electronic devices, and the encoding table 612 is selected from the table options 626 based on identification information of the electronic device 600. In some embodiments, the memory component 606 is a non-volatile programmable memory (e.g., a flash memory). For example, in some embodiments, the memory component 606 includes a one-time programmable (OTP) memory 606P. Further, in some embodiments, the OTP memory 606P is programmed with the table options 626 or only the encoding table 612. Alternatively, in some embodiments not shown, the OTP memory 606P is programmed to store an encoding indicator, which is applied to select the encoding table 612 among the table options 626, and the table options 626 are stored in a distinct non-volatile portion of the memory component 606. The memory component 606 may be included in the memory chip 208 or in the PMIC chip 204T.

In some implementations, at least one of the parameter settings 610 of the individual VRCs of the first group 608 of VRCs 406 includes an indicator referencing data from another portion of the encoding table 612, distinct from and shared by the plurality of VRCs 406. For example, the encoding table 612 includes a set of predefined settings options 628, which may be provided in conjunction with settings from the plurality of register files 614.

In some implementations, for the first group 608 of VRCs 406, at least one of the parameter settings 610 of the individual VRCs includes an indicator referencing data from another portion of the encoding table 612 distinct from and shared by the plurality of register files 614. For example, in some embodiments, a fast transient detection sensitivity 630 has four predefined sensitivity levels stored in the predefined settings options 628, and the first register file 614A uses an indicator (e.g., “0,” “1,” “2,” and “3) to identify a respective sensitivity level used by the first register file 614 to set the first group 608 of VRCs 406.

In some implementations, each respective VRC of the voltage regulation set 410-1 includes regulation control loop circuitry, one or more power stages (e.g., the power stage 518), one or more integrated on-chip inductors (e.g., on-chip inductor 508), and one or more voltage feedback signals (e.g., the voltage signal received on the feedback path 510). Each respective integrated on-chip inductor 508 of the one or more integrated on-chip inductors can be realized by two laminated magnetic thin film pieces surrounding (e.g., wrapping around) a single conductor. In some implementations, each on-chip inductor 508 has one terminal connecting with an output of power stage circuitry of the one or more power stages. In some embodiments, a connection is realized by vias, chip metal layers, and/or a redistribution layer (an RDL).

In some implementations, each respective integrated on-chip inductor 508 also has one output terminal, which has an outward interconnect to bumps or solder balls of the electronic device 600. In some embodiments, the bumps or solder balls are to form the joint connection between PMIC module 112 and an SOC of the electronic device 600. In some embodiments, the bumps or solder balls associated with the inductor 508 output terminals are to be connected to the terminal of the output filter capacitor.

In some implementations, each respective integrated on-chip inductor 508 also includes an inward interconnect (e.g., realized by vias, chip metal layers, an RDL), and the inward interconnect forms a Kelvin connection for sensing a respective current of the respective integrated on-chip inductor 508. In some implementations, the inward interconnect is connected to the current sensing circuitry associated with the corresponding VRC associated with each respective on-chip inductor 508. In some implementation, a sensing distance between two Kelvin sensing contact points on each inductor 508 winding is maintained at a same (e.g., uniform) sensing distance (e.g., for all the integrated inductors 508 of the PMIC).

In some implementations, for a subset of VRCs of the first group 608 of VRCs 406, respective output terminals of the integrated on-chip inductors are connected to an output filter capacitor via interconnects outside of the electronic circuit. In some implementations, for the subset of VRCs, each respective voltage feedback signal is coupled to the output filter capacitor via an interconnect that is not integrated onto the electronic circuit (e.g., outside of the PMIC module 112). In some implementations, the one or more integrated on-chip inductors are fabricated over a footprint of their corresponding VRC. More details on each VRC 406 of the first group 608 of VRCs 406 and associated integrated on-chip inductors 508 are discussed above with reference to FIGS. 4A-5.

In some implementations, the parameter settings 610 stored in the respective register files 614 include parameter settings for controlling the associated operations of electronic components of VRCs 406. For example, the parameter settings 610 include one or more of: (i) a voltage rail identifier (e.g., rail identifier 630-1); (ii) a DAC signal level (e.g., DAC reference 630-2); (iii) a loop gain parameter (main loop gain control 630-3); (iv) a compensation signal parameter (e.g., main loop compensation control 630-4); (v) a sensitivity parameter (e.g., fast transient detection sensitivity 630-5); and (vi) an amplification parameter (e.g., fast transient signal feedback amplification control 630-6).

In some implementations, each VRC 406 includes a regulation control loop circuitry configured to track a difference between a voltage feedback signal and a common voltage reference V_{REF} selected for the respective VRC, and generate, based on the tracked difference between the voltage feedback signal and the common voltage reference, pulse width modulated (PWM) signals driving power stages (e.g., one or more power stages 518). The reference voltage V_{REF} and a gain of the regulation control loop circuit are set based on the parameter settings 610. In some implementations, a VRC 406 includes a transient modulation loop 540 including an amplification and modulation circuit 536 configured for provide a fast transient signal feedback amplification control. The circuit 536 is set based on the amplification control 630-6 of the parameter settings 610 set based on the parameter setting signal 616.

In some embodiments, the parameter settings 610 of the first register file 614A are applied to set all VRCs of the first group 608 of VRCs 406. Alternatively, in some embodiments, the first register file 614A (e.g., selected form the register files 614-1 to 614-8) includes a plurality of cell register files 632 corresponding to individual VRCs 406 within the first group 608. For example, the first group 608 of VRCs 406 includes sixteen or more VRCs, and the first register file 614A includes sixteen cell register files 632. Each register file 632 may provide parameter settings 610 to one or more individual VRCs 406.

In some embodiments, the plurality of register files 614 correspond the plurality of PMIC chips 204, and are stored in a memory component 606, which is a non-volatile memory. In an example, the memory component 606 may be OTP memory 606P (FIG. 6B). In another example, the memory component 606 may be multi-time programmable (MTP) memory. Further, in some embodiments, the plurality of PMIC chips 204 are applied in an SOC-based electronic system 100 that uses a predefined version of the encoding table 612 including the plurality of register files 614, and each PMIC chip 204 includes a respective memory component 606 storing the predefined version of the encoding table 612, which further includes the plurality of register files 614. During operation, each PMIC chip 204 selects a respective register file from the encoding table 612 that is locally stored based on a respective location identification (ID), and the respective PMIC chip 204 further configures its parameter settings 610 based on the selected respective register file.

In some embodiments, a particular power rail 116 is supplied by a respective set of one or more VRCs 406 that may be located on a substrate or distributed across two or more substrates (e.g., substrates 618-1 and 618-2). A unique rail identifier (ID)is assigned to each power rail 116 (e.g., a first power rail 116-1). VRCs 406 associated with a respective power rail 116 are assigned with the unique rail ID. For each respective power rail 116, the VRCs 406 are synchronized to deliver a respective rail voltage V_{RAIL}.

In some implementations, each PMIC chip 204 includes one or more location ID pins to be electrically coupled to a high supply voltage (e.g., 1.8 V) or a low supply voltage (e.g., electrical ground) provided on a package substrate where the respective PMIC chip 204 is mounted. The high supply voltage corresponds to a logic value of “1” or electrical “high,” and the low supply voltage corresponds to a logic value of “0” or electrical “low.” In an example, a PMIC chip 204 includes three pins setting a logic value of its location ID to “011,” when the three pins (e.g., ID pin[2], ID pin[1], ID pin[0]) are electrically coupled to the low supply voltage, the high supply voltage, and the high supply voltage, respectively.

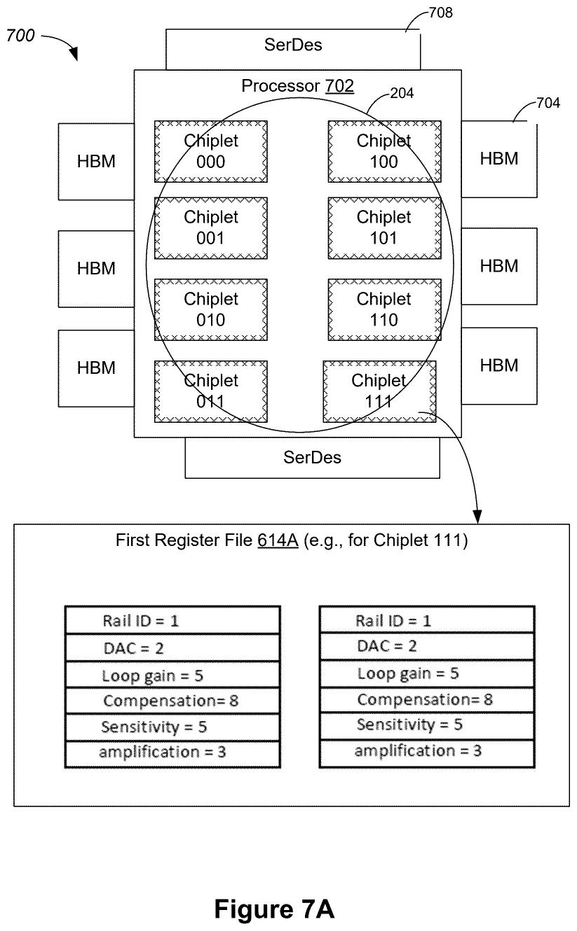

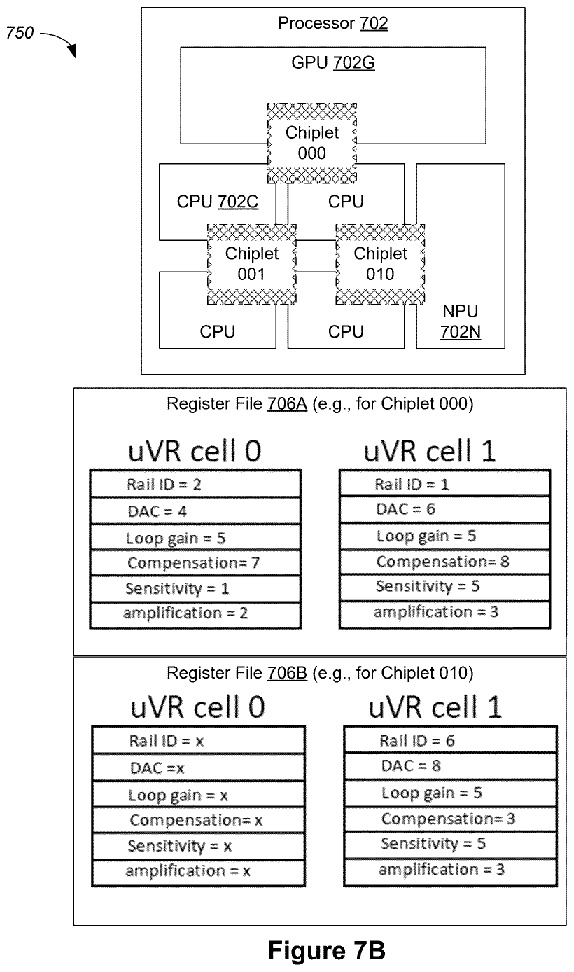

FIGS. 7A and 7B illustrate example electronic systems 700 and 750 and associated parameter settings 610 of VRCs 406, in accordance with some implementations. Each of the electronic systems 700 and 750 includes a different arrangement of chiplets of VRCs, as well as different associated parameter settings 610, which may be configured to correspond to a particular use case of the respective electronic circuits. As a prophetic example, the electronic system 700 includes a server using one or more artificial intelligence (AI) acceleration graphics processing units (GPUs) 702, and the electronic system 750 is an SOC for a personal computer. Though a skilled artisan will understand that many other use cases and configurations for the provided use cases are possible.

Referring to FIG. 7A, in some embodiments, the electronic system 700 includes a processor 702 (e.g., including the AI GPU(s)) and a plurality of PMIC chips 204 (e.g., eight PMIC chips) distributed at different locations with respect to the processor 702. An encoding table 612 is stored in a memory component 606 and includes a plurality of register files (e.g., files 614-1 to 614-8 in FIG. 6A) corresponding to the different locations of the PMIC chips 204. For example, the PMIC chips 204 include a chiplet 000, and a first register file 614A corresponding to the chiplet 000 is extracted from the encoding table 612 and applied to provide parameter settings 610 of individual VRCs 406 of the chiplet 000. In this example (FIG. 7A), the first group 608 of VRCs 406 of the chiplet 000 includes two VRCs 406 configured to provide a rail voltage jointly. These two VRCs 406 have the same parameter settings 610 (e.g., Rail ID=1, DAC=2, Loop gain=5, Compensation=8, Sensitivity=5, and Amplification=3). It is noted that, in some situations, each of the parameter settings 610 is defined by a respective indicator (e.g., “1,” “2,” “5”) for selecting one of a set of predefined settings options 628 (FIG. 6B).

In some embodiments, the electronic system 700 includes one or more high bandwidth memories (HBMs) 704, which are coupled to the processor module 102 and/or the PMIC chips 204 by a serial communication bus. Further, in some embodiments, the memory component 606 stores the encoding table 612 is included in the HBMs 704. Alternatively, in some embodiments, the memory component 606 is integrated on the PMIC chips 204.

Referring to FIG. 7B, in some embodiments, the electronic system 750 includes a processor 702 having a plurality of distinct processor units (e.g., CPU 702C, GPU 702G, NPU 702N) and a plurality of PMIC chips 204 (e.g., three PMIC chips labelled as “Chiplet 000,” “Chiplet 001,” and “Chiplet 010”) distributed at respective locations with respect to the processor 702. An encoding table 612 is stored in a memory component 606 and includes a plurality of register files (e.g., files 614-1 to 614-8 in FIG. 6A) corresponding to the different locations of the PMIC chips 204. For example, the PMIC chips 204 include a chiplet 000 and a chiplet 010, and two register files 706A and 706B corresponding to the chiplets 000 and 010 are extracted from the encoding table 612 and applied to provide parameter settings 610 of individual VRCs 406 of the chiplets 000 and 010. In this example (FIG. 7B), for the chiplet 000, the first group 608 of VRCs 406 includes two VRCs 406 configured to provide two distinct rail voltages (e.g., having two distinct rail identifiers of “2” and “1”). These two VRCs 406 have the same parameter settings 610 for Loop Gain, but not for the other parameter settings (e.g., Compensation, Sensitivity, and Amplification).

In some embodiments, the parameter settings 610 of a VRC 406 (e.g., “uVR cell 1” for the chiplet 010) are predefined. Conversely, in some embodiments, the parameter settings 610 of a VRC 406 (e.g., “uVR cell 0” for the chiplet 010) are undefined or represented by a variable (e.g., “x”), and dynamically defined when the VRC 406 is applied to drive a power rail 116. Alternatively, in some embodiments, the parameter settings 610 of a VRC 406 (e.g., “uVR cell 0” for the chiplet 010) are undefined or represented by a variable (e.g., “x”), indicating that the VRC 406 is not applied to drive any power rail 116.

In some embodiments, the plurality of PMIC chips 204 provide power via the plurality of power rails 116 to GPU cores 702G, HBMs 704, and/or a serializer/deserializer component 708. Each VRC 406 is configured to contribute to a respective power rail based on a location of the respective VRC 406. For instance, for general-purpose GPUs, the plurality of PMIC chips 204 are configured to drive a GPU power rail, an HBM power rail, and a serializer power rail, and the VRCs 406 of the plurality of PMIC chips 204 are grouped into three sets to drive the GPU power rail, the HBM power rail, and the serializer power rail, respectively. In an example, chiplet 001 includes two subsets of VRCs that supply power to the GPU cores 702G and the HBMs 704, respectively. Chiplet 001 may contribute to all or a portion of power consumption needed by each power rail 116 driving the GPU cores 702G and the HBMs 704.

In some embodiments, each respective PMIC chip 204 includes a plurality of VRCs 406 forming an array of VRCs 406. Each VRC 406 has a respective loop control circuitry. For a particular power rail 116, a respective set of VRCs 406 is grouped to supply power jointly to the particular power rail 116, and rail voltage setpoints (also called voltage identification (VID)) associated with respective set of VRCs 406 are adjusted in a synchronous manner. The respective set of VRCs 406 associated with the particular power rail 116 may be provided by the same PMIC chip 204. Alternatively, the respective set of VRCs 406 associated with the particular power rail 116 may be provided by two or more distinct PMIC chips 204 that are synchronized with one another. In accordance with some embodiments of this application is at least a realization that it is difficult to direct ID change commands to, and synchronize changes of rail voltages V_{RAIL} outputted by, the two or more distinct PMIC chips 204, while the VIDs are sequentially addressed and programmed to the two or more distinct PMIC chips 204.

Some implementations of this application are directed to applying a hardware scheme to virtualize physical locations of the VRCs 406. In accordance with the hardware scheme, the configuration register files define associated power rails 116 and control logic links of individual VRCs 406 of each PMIC chip 204. Characteristics of each power rail 116 are programmed using rail ID based commands, which are addressed to the plurality of PMIC chips 204 and associated VRCs 406, independently of physical locations of individual PMIC chips 204. Stated another way, in some embodiments, a rail identifier is a unique number identifying a corresponding power rail 116 in the electronic system 100.

FIG. 8 is a block diagram of an example electronic system 800 including a plurality of PMIC chips 204 (also called power chiplets 204), in accordance with some embodiments. The electronic system 800 includes a plurality of power rails 116 (e.g., power rail 116-1, 116-2), the plurality of power chiplets 204 (e.g., power chiplet 204-1, 204-2) coupled to the plurality of power rails 116, and a power broadcast interface 802 coupled to the plurality of power chiplets 116. Each power chiplet 204 includes a plurality of respective voltage regulator cells (VRCs) 406, and each of the plurality of respective VRCs 406 is configured to output a respective programmable rail voltage V_{RAIL} to a respective one of the plurality of power rails 116. The power broadcast interface 802 is configured to broadcast a power control command 804 to the plurality of power chiplets 204, and the power control command 804 includes at least a rail identifier 808 identifying a first power rail 116-1. The power control command 804 is not targeted at a specific power chiplet 204. In some embodiments, the electronic system 800 includes a system controller 806 coupled to the power broadcast interface 802. The system controller 806 is configured to generate the power control command 804 and provide the power control command 804 to the power broadcast interface 802. Each of a subset of power chiplets 204S is configured to decode the power control command 804, and select a respective set of VRCs 406S among the plurality of respective VRCs 406 based on the rail identifier 808 to provide power to the first power rail 116-1. Referring to FIG. 8, in this example, the subset of power chiplets 204S includes a first power chiplet 204-1, a second power chiplet 204-2, and a third power chiplet 204-3. A first rail voltage V_{RAIL1} of the first power rail 116-1 is provided jointly by six VRCs 406-1 (e.g., two on the first row, three on the third row, two on the fourth row) of the first power chiplet 204-1, two VRCs 406-2 on the third row of the second power chiplet 204-2, and four VRCs 406-3 on the first row of the third power chiplet 204-3.

In some embodiments, the plurality of power chiplets 204 further include at least one remaining power chiplet 204R that is distinct from the subset of power chiplets 204S. The at least one remaining power chiplet 204R does not include any VRCs 406 configured (e.g., by an associated configuration register file 614) to provide power to the first power rail 116-1, and is configured to provide no power to the first power rail 116-1. In other words, the subset of power chiplets 204S includes less than all of the plurality of power chiplets 204 included in the electronic system 800. Further, in some embodiments, the at least one remaining power chiplet 204R is configured to receive and decode the power control command 804 and determine that none of the plurality of respective VRCs 406 located on the at least one remaining power chiplet 204R corresponds to the rail identifier 808.

Stated another way, in some situations, each of the plurality of power chiplets 204 receives and decodes the power control command 804, independently of whether the respective power chiplet 204 has any VRC 406 selected to drive a power rail 116 that is identified by the rail identifier 808 of the power control command 804. The power chiplet 204 extracts the rail identifier 808 from the power control command 804. Further, in some embodiments, no VRC 406 of the respective power chiplet 204 (e.g., power chiplet 204R) matches the extracted rail identifier 808 or is not controlled by operation parameters of the power control command 804 associated with the rail identifier 808. Conversely, in some embodiments, a respective set of VRCs 406S of the respective power chiplet 204 (e.g., power chiplet 204-1) matches the extracted rail identifier 808, and is therefore controlled by operation parameters of the power control command 804 associated with the rail identifier 808 to provide power to the power rail 116 identified by the rail identifier 808.

In some embodiments, the power control command 804 further includes an operation identifier 810 and an operation parameter 812, and each of the subset of power chiplets 204S is configured to power the first power rail 116-1 using a first power operation identified by the operation identifier 810 based on the operation parameter 812. The operation identifier 810 and the operation parameter 812 correspond to rail voltage setpoints (also called voltage identification (VID)), which are applied to define the first power operation that generates the first rail voltage V_{RAIL1}. Further, in some embodiments, the first power operation is identified by the operation identifier 810 among a plurality of predefined power operations including a rail telemetry extraction operation 810-1, a rail voltage adjustment operation 810-2, a rail startup operation 810-3, a rail shutdown operation 810-4, and a VRC bandwidth adjustment operation 810-5. In some embodiments, the operation parameter 812 corresponds to one or more of: a DAC reference 812-1, a loop gain 812-2, a compensation 812-3, a fast transient detection sensitivity 812-4, and a fast transient signal feedback amplification control 812-5. More details on the operation parameters 812 are discussed above with reference to different parameter settings 610 in FIG. 6B.

In some embodiments, the power broadcast interface 802 is configured to broadcast the power control command 804 to the plurality of power chiplets 204 according to a predefined serial communication protocol, and the power control command 804 follows a predefined data format. For example, the predefined serial communication protocol includes a two-wire serial communication protocol, Inter-Integrated Circuit (I2C). Stated another way, on a physical layer, the power broadcast interface 802 utilizes an interface scheme (e.g., I2C) to support a plurality of slaves (e.g., a plurality of power chiplets 204), and the power control command 804 is broadcast to the plurality of slaves from the system controller 806.

In some embodiments, in accordance with the predefined data format, the power control command 804 includes a header 814, a rail identifier 808, an operation identifier 810, one or more operation parameters 812. Further, in some embodiments, the power control command 804 includes an ordered sequence of rail defining data sets, e.g., a first rail identifier 808 and an associated operation identifier 810 and one or more associated operation parameters 812, a second rail identifier 818 and an associated operation identifier 820 and one or more associated operation parameters 822. Alternatively, in some embodiments, a sequence of power control commands 804 is broadcast to provide the ordered sequence of rail defining data sets, and each power control command 804 includes one or more respective rail defining data sets, each including a respective rail identifier, an associated operation identifier, and one or more associated operation parameters.

In some embodiments, the electronic system 800 further includes one or more processors powered by the plurality of power rails 116 carrying the plurality of rail voltages V_{RAIL}. In some embodiments, a power management system is formed by the plurality of power rails 116, the plurality of power chiplets 204, the power broadcast interface 802, and the system controller 806, and further integrated with one or more processors (e.g., CPU, GPU) to be powered by the plurality of rail voltages V_{RAIL} in a system on chip (SOC). More details on an electronic system including an SOC are discussed with reference to FIGS. 2A, 2B, 3A, and 3B.

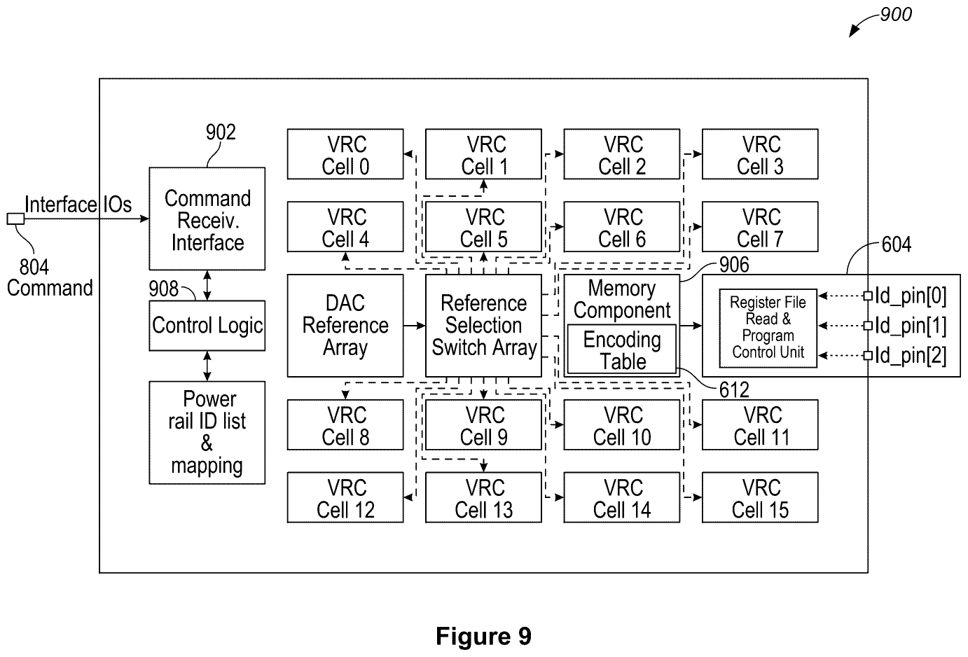

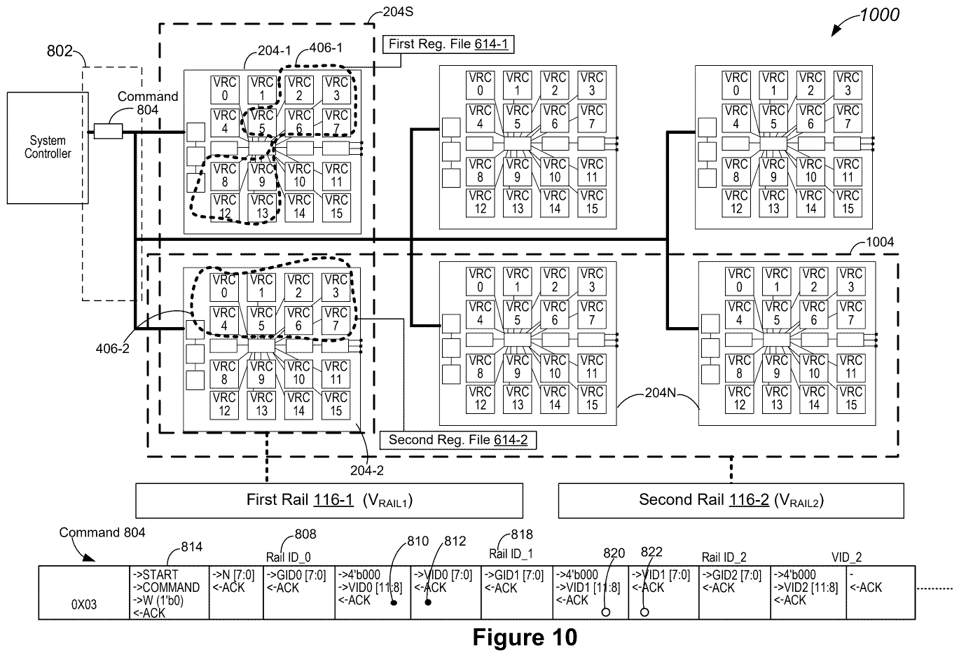

FIG. 9 is a block diagram of an example power chiplet 204 including a programmable power array of VRCs 406, in accordance with some embodiments. The power chiplet 204 is coupled to a power broadcast interface 802 (FIG. 8). The power broadcast interface 802 is configured to broadcast a power control command 804 to the power chiplet 204, e.g., without differentiating the power chiplet 204 from other power chiplets in the same electronic system 800. In other words, the power control command 804 is not targeted at a specific power chiplet 204. The power control command 804 includes at least a rail identifier 808 identifying a first power rail 116-1. The power chiplet 204 includes a plurality of respective voltage regulator cells (VRCs) 406, and each of the plurality of respective VRCs is configured to output a respective programmable rail voltage V_{RAIL} to a respective one of the plurality of power rails 116. Upon receiving the power control command 804, the power chiplet 204 decodes the power control command 804, and in some embodiments, selects a respective set of VRCs 406S among the plurality of respective VRCs 406 based on the rail identifier 808 to provide power to a power rail identified by the rail identifier 808 (e.g., the first power rail 116-1). Conversely, in some embodiments, the power chiplet 204 (e.g., a remaining power chiplet 204R in FIG. 8) determines that none of the plurality of VRCs 406 of the power chiplet 204 matches the rail identifier 808 of the power control command 804.

In some embodiments, the power chiplet 204 includes, or is coupled to, a memory component 906 (e.g., memory component 606 in FIG. 6A). The memory component 906 stores an encoding table 612 including a plurality of register files 614 corresponding to a plurality of power chiplets 204 of an electronic system 800. Each register file 614 corresponds to a power chiplet 204 (e.g., the first power chiplet 204-1 in FIG. 8), and defines parameter settings 610 for the plurality of respective VRCs 406 of the corresponding power chiplet 204. For each of the plurality of respective VRCs 406 of the corresponding power chiplet 204, the parameter settings 610 identify the respective one of the plurality of power rails 116 to which the respective VRC 406 is coupled, and in some embodiments, may define the respective programmable rail voltage V_{RAIL} of the respective one of the plurality of power rails 116.

Further, in some embodiments, the power chiplet 204 further comprises a command receiving interface 902 coupled to the power broadcast interface 802. The command receiving interface 902 is configured to receive the power control command 804. A setting interface 604 is electrically coupled to the memory component 606, and is configured to load a respective register file 614 from the memory component 606. The setting interface 604 is distinct from the command receiving interface.

FIG. 10 is a block diagram of another example electronic system 1000 providing power to at least two power rails 116 (e.g., first power rail 116-1, second power rail 116-2), in accordance with some embodiments. The electronic system 1000 includes a plurality of power rails 116 (e.g., power rail 116-1, 116-2), the plurality of power chiplets 204 (e.g., power chiplet 204-1, 204-2), and a power broadcast interface 802. Each power chiplet 204 includes a plurality of respective VRCs 406, and each VRC 406 configured to output a respective programmable rail voltage V_{RAIL} to a respective power rail 116. The power broadcast interface 802 is configured to broadcast a power control command 804 to the plurality of power chiplets 204. The power control command 804 is not targeted at a specific power chiplet 204 and includes at least a rail identifier 808 identifying a first power rail 116-1. Each of a subset of power chiplets 204S (e.g., power chiplets 204-1 and 204-2) is configured to decode the power control command 804, and select a respective set of VRCs 406S among the plurality of respective VRCs 406 based on the rail identifier 808 to provide power to the first power rail 116-1.

In some embodiments, the subset of power chiplets 204S include a first power chiplet 204-1 and a second power chiplet 204-2. The first power chiplet 204-1 is configured to identify the first power rail 116-1 based on the rail identifier 808 of the power control command 804, select a first set of VRCs 406-1 corresponding to the first power rail 116-1, and output a first rail voltage V_{RAIL1} to the first power rail 116-1 via the first set of VRCs 406-1. The second power chiplet 116-2 is configured to identify the first power rail 116-1 based on the rail identifier 808 of the power control command 804, select a second set of VRCs 406-2 corresponding to the first power rail 116-1, and output the first rail voltage V_{RAIL1} to the first power rail 116-1 via the second set of VRCs 406-2. Both the first set of VRCs 406-1 of the first power chiplet 204-1 and the second set of VRCs 406-2 of the second power chiplet 204-2 are electrically coupled to the first power rail 116-1.

Further, in some embodiments, the first power chiplet 204-1 is configured to select the first set of VRCs 406-1 corresponding to the first power rail 116-1 based on a first register file 614-1, and the second power chiplet 204-2 is configured to select the second set of VRCs 406-2 corresponding to the first power rail V_{RAIL1} based on a second register file 614-2. The first power chiplet 204-1 may extract the first register file 614-1 stored locally in a corresponding memory component, and the second power chiplet 204-2 may extract the second register file 614-2 stored locally in a corresponding memory component. In some embodiments, the first power chiplet 204-1 and the second power chiplet 204-2 are identical chiplets, and disposed at different locations of an SOC. Each of the first power chiplet 204-1 and the second power chiplet 204-2 obtains a respective set of location-based pin values (e.g., 111, 110, 011) via a respective setting interface 604 (FIGS. 6A and 9), selects the respective register file 614-1 or 614-2, and controls respective VRCs 406 to output their respective rail voltages V_{RAIL} to the respective power rails 116 based on the respective register file 614-1 or 614-2.

In some embodiments, the first set of VRCs 406-1 has a different number of VRCs from the second set of VRCs 406-2. For example, the first set of VRCs 406-1 includes 9 VRCs, and the second set of VRCs 406-2 includes 8 VRCs. Alternatively, in some embodiments not shown in FIG. 10, the first set of VRCs 406-1 has the same number of VRCs as the second set of VRCs 406-2, and at least one of the first set of VRCs 406-1 is different from any of the second set of VRCs in a location in a corresponding chiplet 204. Alternatively, in some embodiments not shown in FIG. 10, the first set of VRCs 406-1 and the second set of VRCs 406-2 are identical to one another, in both the number of VRCs and locations in their respective power chiplets 204.

In some embodiments, the rail identifier 808 includes a first rail identifier 808, and the power control command 804 further includes a second rail identifier 818 identifying a second power rail 116-2. The plurality of power chiplets 204 are configured to power the first power rail 116-1 in synchronization with the second power rail 116-2 based on the power control command 804. A second power operation may be applied on the second power rail 116-2 in phase with a first power operation applied on the first power rail 116-1. Alternatively, the second power operation may be delayed by a predefined time with reference to the first operation. Further, in some embodiments, each of a second subset of power chiplets 1004 includes at least one respective VRC 406 selected to provide power to the second power rail 116-2 based on the power control command 804. More specifically in some embodiments, the subset of power chiplets 204S includes a first subset of power chiplets, and each of the second subset of power chiplets 1004 is configured to receive and decode the power control command 804, select one or more respective VRCs 406 based on the second rail identifier 818 (FIG. 8) to provide power to the second power rail 116-2. At least one of the second subset of power chiplets 1004 (e.g., power chiplets 204N in FIG. 10) is included in the first subset of power chiplets 204S.

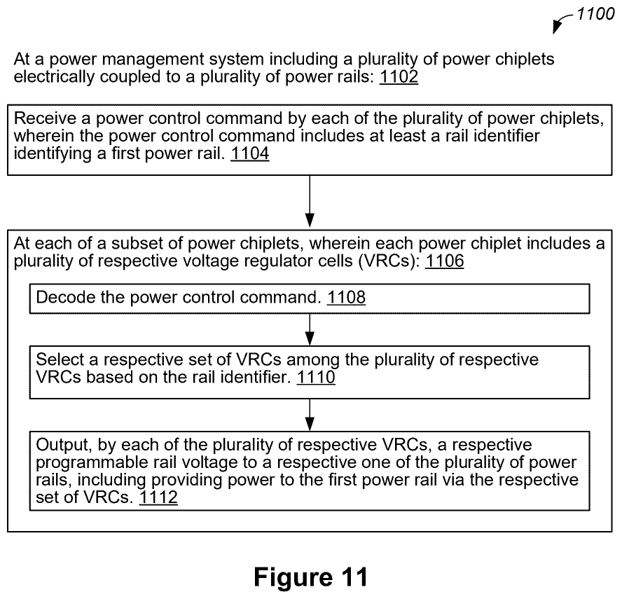

FIG. 11 is a flow diagram of an example method 1100 for providing power to one or more power rails 116, in accordance with some embodiments. The method 1100 is implemented (operation 1102) by an electronic system (e.g., electronic systems 800 and 1000) including a plurality of power chiplets 204 electrically coupled to the one or more power rails 116. Each of the plurality of power chiplets 204 of the electronic system receives (operation 1104) a power control command 804 including at least a rail identifier 808 identifying a first power rail 116-2. Each power chiplet 204 includes (operation 1106) a plurality of respective VRCs 406. Each of a subset of power chiplets 204S decodes (operation 1108) the power control command, selects (operation 1110) a respective set of VRCs 406S among the plurality of respective VRCs 406 based on the rail identifier 808, and outputs (operation 1112), via each of the plurality of respective VRCs 406, a respective programmable rail voltage V_{RAIL} to a respective one of the plurality of power rails 116, including providing power to the first power rail 116-1 via the respective set of VRCs 406S.

In some embodiments, the power control command 804 further includes an operation identifier 810 and an operation parameter 812. Each of the subset of power chiplets 204S provides power to the first power rail 116-1 using a first power operation identified by the operation identifier 810 based on the operation parameter 812. Further, in some embodiments, the first power operation is identified among a plurality of predefined power operations including a rail telemetry extraction operation 810-1, a rail voltage adjustment operation 810-2, a rail startup operation 810-3, a rail shutdown operation 810-4, and a VRC bandwidth adjustment operation 814-5. In some embodiments, the operation parameter 812 corresponds to one or more of: a DAC reference 812-1, a loop gain 812-2, a compensation 812-3, a fast transient detection sensitivity 812-4, and a fast transient signal feedback amplification control 812-5.

In some embodiments, the rail identifier 808 includes a first rail identifier, and the power control command 804 further includes a second rail identifier 818 (FIG. 8) identifying a second power rail 116-2, and the plurality of power chiplets 204 powers the first power rail 116-1 in synchronization with the second power rail 116-2 based on the power control command 804. Further, in some embodiments (FIG. 10), the subset of power chiplets 204S includes a first subset of power chiplets, and each of a second subset of power chiplets 1004 receives and decodes the power control command 804, and selects one or more respective VRCs 406 based on the second rail identifier 818 to provide power to the second power rail 116-2. At least one of the second subset of power chiplets 1004 is not included in the first subset of power chiplets 204S.

In some embodiments, a memory component 606 is coupled to, or included in each of, the plurality of power chiplets 204. The memory component 606 stores an encoding table 612 including a plurality of register files 614 (FIG. 6B). Each register file 614 defines parameter settings 610 for the plurality of respective VRCs 406 of a corresponding power chiplet 204. For each of the plurality of respective VRCs 406 of the corresponding power chiplet 204, the parameter settings 610 identify the respective one of the plurality of power rails to which the respective VRC 406 is coupled, and define the respective programmable rail voltage V_{RAIL} of the respective one of the plurality of power rails 116. Further, in some embodiments, in each of the plurality of power chiplets 204, a command receiving interface 902 is coupled to the power broadcast interface 802, and receives the power control command 804. A setting interface 604 is electrically coupled to the memory component 606, and loads a respective register file 614 from the memory component 606. The setting interface 604 is distinct from the command receiving interface 902.

In some embodiments, the subset of power chiplets 204S includes only a first power chiplet 204-1, and the first power chiplet 204-1 identifies the first power rail 116-1 based on the rail identifier 808 of the power control command 804, selects a first set of VRCs 406-1 corresponding to the first power rail 116-1, and outputs a first rail voltage V_{RAIL} to the first power rail 116-1 via the first set of VRCs 406-1.

In some embodiments, the subset of power chiplets 204S includes a first power chiplet 204-1 and a second power chiplet 204-2. The first power chiplet 204-1 identifies the first power rail 116-1 based on the rail identifier 808 of the power control command 804, selects a first set of VRCs 406-1 corresponding to the first power rail 116-1, and outputs a first rail voltage V_{RAIL1} to the first power rail 116-1 via the first set of VRCs 406-1. The second power chiplet 204-2 identifies the first power rail 116-1 based on the rail identifier 808 of the power control command 804, selects a second set of VRCs 406-2 corresponding to the first power rail 116-1, and outputs the first rail voltage V_{RAIL1} to the first power rail 116-1 via the second set of VRCs 406-2. Both the first set of VRCs 406-1 of the first power chiplet 204-1 and the second set of VRCs 406-2 of the second power chiplet 204-2 are electrically coupled to the first power rail 116-1. Further, in some embodiments, the first power chiplet 204-1 selects a first set of VRCs 406-1 corresponding to the first power rail 116-1 based on a first register file 614-1, and the second power chiplet 204-2 selects a second set of VRCs 406-2 corresponding to the first power rail 116-1 based on a second register file 614-2.

In some embodiments, the plurality of power chiplets 204 further includes at least one remaining power chiplet 204R that is distinct from the subset of power chiplets 204R. The at least one remaining power chiplet 204R does not include any VRCs 406 configured to provide power to the first power rail 116-1, and provides no power to the first power rail 116-1. Further, in some embodiments, the at least one remaining power chiplet 204R receives and decodes the power control command 804 and determines that none of the plurality of respective VRCs 406 corresponds to the rail identifier 808.

In some embodiments, the power broadcast interface 802 broadcasts the power control command 804 to the plurality of power chiplets 204 according to a predefined serial communication protocol, and the power control command follows a predefined data format.

In some embodiments, a plurality of power chiplets 204 are used to power multiple power rails 116 of the CPUs and GPUs. Each power chiplet 204 includes an array of VRCs 406. Any number of VRCs 406 can be grouped to form a respective power rail 116 for a targeted GPU/CPU power rail. VRCs 406 across multiple chiplets 204 can be grouped together to form a respective power rail 116. In some embodiments, synchronous control operation to a group of VRCs 406 can be initiated by the system controller without knowing or identifying the physical location and the number of VRCs 406 of such VRC group.

In some embodiments, a unique number is assigned to each VRC group. This number represents a unique rail identifier of a given power rail (e.g., rail identifier 808 of the first power rail 116-1).

In some embodiments, the association of a VRC 406 with a rail identifier is stored in a configuration register file 614 in the form of non-volatile memory (e.g., a memory component 606) on a power chiplet 204.

In some embodiments, each power chiplet 204 initializes grouping of VRCs 406 based on the register file portion indexed by signal inputs obtained via a location ID interface (e.g., a setting interface 604 in FIGS. 6 and 9).

In some embodiments, a power chiplet 204 configures power rail based hardware controls of VRCs 406, which are associated with the same rail identifier 808 in the power chiplet 204, after loading the corresponding register file 614 and setting control registers.

In some embodiments, a system controller 806 of an electronic system broadcasts a rail identifier 808 using the power control command 804 to all chiplets 204 via a control interface bus 824 (FIG. 8).

In some embodiments, a first chiplet 204-1 receives a rail identifier based command (e.g., power control command 804) from the system controller 806, and finds itself has a first set of one or more VRCs 406-1 associated with the rail identifier 808. The first chiplet 204-1 applies a control logic 908 (FIG. 9) to change the settings of the first set of one or more VRCs 406-1 in a synchronous manner.

In some embodiments, each power chiplet 204 includes an array of DACs generating reference voltage signals for VRCs 406. In a first power chiplet 204-1, a rail identifier 808 is associated with a first set of VRCs 406-1, and mapped or linked to a DAC module of the array of DACs according to a configuration register file 614 (FIG. 6B).

Numerous examples of aspects of the disclosure are described as numbered clauses (1, 2, 3, etc.) for convenience. These are provided as examples, and do not limit the subject technology. Identifications of the figures and reference numbers are provided below merely as examples and for illustrative purposes, and the clauses are not limited by those identifications.

Clause 1. A power management system, comprising: a plurality of power rails configured to provide a plurality of rail voltages; a plurality of power chiplets coupled to the plurality of power rails, wherein each power chiplet includes a plurality of respective voltage regulator cells (VRCs), and each of the plurality of respective VRCs is configured to output a respective programmable rail voltage to a respective one of the plurality of power rails; a power broadcast interface coupled to the plurality of power chiplets, wherein the power broadcast interface is configured to broadcast a power control command to the plurality of power chiplets and the power control command includes at least a rail identifier identifying a first power rail; wherein each of a subset of power chiplets is configured to decode the power control command, and select a respective set of VRCs among the plurality of respective VRCs based on the rail identifier to provide power to the first power rail.

Clause 2. The power management system of claim 1, wherein the power control command further includes an operation identifier and an operation parameter, and each of the subset of power chiplets is configured to power the first power rail using a first power operation identified by the operation identifier based on the operation parameter.

Clause 3. The power management system of claim 2, wherein the first power operation is identified among a plurality of predefined power operations including a rail telemetry extraction operation, a rail voltage adjustment operation, a rail startup operation, a rail shutdown operation, and a VRC bandwidth adjustment operation.

Clause 4. The power management system of claim 2, wherein the operation parameter corresponds to one or more of: a digital-to-analog (DAC) reference, a loop gain, a compensation, a fast transient detection sensitivity, and a fast transient signal feedback amplification control.

Clause 5. The power management system of claim 1, wherein the rail identifier includes a first rail identifier, and the power control command further includes a second rail identifier identifying a second power rail, and the plurality of power chiplets are configured to power the first power rail in synchronization with the second power rail based on the power control command.

Clause 6. The power management system of claim 5, wherein the subset of power chiplets includes a first subset of power chiplets, and each of a second subset of power chiplets is configured to receive and decode the power control command, select one or more respective VRCs based on the second rail identifier to provide power to the second power rail, at least one of the second subset of power chiplets not included in the first subset of power chiplets.

Clause 7. The power management system of claim 1, wherein: a memory component coupled to, or included in each of, the plurality of power chiplets, wherein the memory component stores an encoding table including a plurality of register files, each register file defining parameter settings for the plurality of respective VRCs of a corresponding power chiplet; wherein for each of the plurality of respective VRCs of the corresponding power chiplet, the parameter settings identify the respective one of the plurality of power rails to which the respective VRC is coupled, and define the respective programmable rail voltage of the respective one of the plurality of power rails.

Clause 8. The power management system of claim 7, wherein each of the plurality of power chiplets further comprises: a command receiving interface coupled to the power broadcast interface, the command receiving interface configured to receive the power control command; and a setting interface electrically coupled to the memory component, and is configured to load a respective register file from the memory component; wherein the setting interface is distinct from the command receiving interface.

Clause 9. The power management system of claim 1, wherein the subset of power chiplets include only a first power chiplet, and the first power chiplet is configured to identify the first power rail based on the rail identifier of the power control command, select a first set of VRCs corresponding to the first power rail, and output a first rail voltage to the first power rail via the first set of VRCs.

Clause 10. The power management system of claim 1, wherein: the subset of power chiplets include a first power chiplet and a second power chiplet; the first power chiplet is configured to identify the first power rail based on the rail identifier of the power control command, select a first set of VRCs corresponding to the first power rail, and output a first rail voltage to the first power rail via the first set of VRCs; the second power chiplet is configured to identify the first power rail based on the rail identifier of the power control command, select a second set of VRCs corresponding to the first power rail, and output the first rail voltage to the first power rail via the second set of VRCs; and both the first set of VRCs of the first power chiplet and the second set of VRCs of the second power chiplet are electrically coupled to the first power rail.

Clause 11. The power management system of claim 10, wherein the first power chiplet is configured to select a first set of VRCs corresponding to the first power rail based on a first register file, and the second power chiplet is configured to select a second set of VRCs corresponding to the first power rail based on a second register file.

Clause 12. The power management system of claim 10, wherein the first set of VRCs has a different number of VRCs from the second set of VRCs.

Clause 13. The power management system of claim 10, wherein the first set of VRCs has the same number of VRCs as the second set of VRCs, and at least one of the first set of VRCs is different from any of the second set of VRCs in a location in a corresponding chiplet.

Clause 14. The power management system of claim 1, wherein the plurality of power chiplets further includes at least one remaining power chiplet that is distinct from the subset of power chiplets, and the at least one remaining power chiplet does not include any VRCs configured to provide power to the first power rail, and is configured to provide no power to the first power rail.

Clause 15. The power management system of claim 14, wherein the at least one remaining power chiplet is configured to receive and decode the power control command and determine that none of the plurality of respective VRCs corresponds to the rail identifier.

Clause 16. The power management system of claim 1, wherein the power broadcast interface is configured to broadcast the power control command to the plurality of power chiplets according to a predefined serial communication protocol, and the power control command follows a predefined data format.

Clause 17. The power management system of claim 1, wherein the power management system is integrated with one or more processors to be powered by the plurality of rail voltages in a system on a chip (SOC).

Clause 18. An electronic device, comprising: one or more processors powered by a plurality of rail voltages; a plurality of power rails configured to provide a plurality of rail voltages; a plurality of power chiplets coupled to the plurality of power rails, wherein each power chiplet includes a plurality of respective voltage regulator cells (VRCs), and each of the plurality of respective VRCs is configured to output a respective programmable rail voltage to a respective one of the plurality of power rails; a power broadcast interface coupled to the plurality of power chiplets, wherein the power broadcast interface is configured to broadcast a power control command to the plurality of power chiplets and the power control command includes at least a rail identifier identifying a first power rail; wherein each of a subset of power chiplets is configured to decode the power control command, and select a respective set of VRCs among the plurality of respective VRCs based on the rail identifier to provide power to the first power rail.

Clause 19. A method, comprising: at a power management system including a plurality of power chiplets electrically coupled to a plurality of power rails: receiving a power control command by each of the plurality of power chiplets, wherein the power control command includes at least a rail identifier identifying a first power rail, and wherein; and at each of a subset of power chiplets, wherein each power chiplet includes a plurality of respective voltage regulator cells (VRCs): decoding the power control command; selecting a respective set of VRCs among the plurality of respective VRCs based on the rail identifier; and outputting, by each of the plurality of respective VRCs, a respective programmable rail voltage to a respective one of the plurality of power rails, including providing power to the first power rail via the respective set of VRCs.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

It is known to one of those skilled in the art that “chip” and “chiplet” may be used in an exchangeable manner under some circumstances in this application.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific implementations. However, the illustrative discussions above are not intended to be exhaustive or to limit the claims to the precise forms disclosed. Many modifications and variations are possible in view of the above teachings. The implementations were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software, or any combination thereof.

What is claimed is:

1. A power management system, comprising:
a plurality of power rails configured to provide a plurality of rail voltages;
a plurality of power chiplets coupled to the plurality of power rails, wherein each power chiplet includes a plurality of respective voltage regulator cells (VRCs), and each of the plurality of respective VRCs is configured to output a respective programmable rail voltage to a respective one of the plurality of power rails;
a power broadcast interface coupled to the plurality of power chiplets, wherein the power broadcast interface is configured to broadcast a power control command to the plurality of power chiplets and the power control command includes at least a rail identifier identifying a first power rail;
wherein each of a subset of power chiplets is configured to decode the power control command, and select a respective set of VRCs among the plurality of respective VRCs based on the rail identifier to provide power to the first power rail.

2. The power management system of claim 1, wherein the power control command further includes an operation identifier and an operation parameter, and each of the subset of power chiplets is configured to power the first power rail using a first power operation identified by the operation identifier based on the operation parameter.

3. The power management system of claim 2, wherein the first power operation is identified among a plurality of predefined power operations including a rail telemetry extraction operation, a rail voltage adjustment operation, a rail startup operation, a rail shutdown operation, and a VRC bandwidth adjustment operation.

4. The power management system of claim 2, wherein the operation parameter corresponds to one or more of: a digital-to-analog (DAC) reference, a loop gain, a compensation, a fast transient detection sensitivity, and a fast transient signal feedback amplification control.

5. The power management system of claim 1, wherein the rail identifier includes a first rail identifier, and the power control command further includes a second rail identifier identifying a second power rail, and the plurality of power chiplets are configured to power the first power rail in synchronization with the second power rail based on the power control command.

6. The power management system of claim 5, wherein the subset of power chiplets includes a first subset of power chiplets, and each of a second subset of power chiplets is configured to receive and decode the power control command, select one or more respective VRCs based on the second rail identifier to provide power to the second power rail, at least one of the second subset of power chiplets not included in the first subset of power chiplets.

7. The power management system of claim 1, wherein:
a memory component coupled to, or included in each of, the plurality of power chiplets, wherein the memory component stores an encoding table including a plurality of register files, each register file defining parameter settings for the plurality of respective VRCs of a corresponding power chiplet;
wherein for each of the plurality of respective VRCs of the corresponding power chiplet, the parameter settings identify the respective one of the plurality of power rails to which the respective VRC is coupled, and define the respective programmable rail voltage of the respective one of the plurality of power rails.

8. The power management system of claim 7, wherein each of the plurality of power chiplets further comprises:
a command receiving interface coupled to the power broadcast interface, the command receiving interface configured to receive the power control command; and
a setting interface electrically coupled to the memory component, and is configured to load a respective register file from the memory component;
wherein the setting interface is distinct from the command receiving interface.

9. The power management system of claim 1, wherein the subset of power chiplets include only a first power chiplet, and the first power chiplet is configured to identify the first power rail based on the rail identifier of the power control command, select a first set of VRCs corresponding to the first power rail, and output a first rail voltage to the first power rail via the first set of VRCs.

10. The power management system of claim 1, wherein:
the subset of power chiplets include a first power chiplet and a second power chiplet;
the first power chiplet is configured to identify the first power rail based on the rail identifier of the power control command, select a first set of VRCs corresponding to the first power rail, and output a first rail voltage to the first power rail via the first set of VRCs;
the second power chiplet is configured to identify the first power rail based on the rail identifier of the power control command, select a second set of VRCs corresponding to the first power rail, and output the first rail voltage to the first power rail via the second set of VRCs; and
both the first set of VRCs of the first power chiplet and the second set of VRCs of the second power chiplet are electrically coupled to the first power rail.

11. The power management system of claim 10, wherein the first power chiplet is configured to select a first set of VRCs corresponding to the first power rail based on a first register file, and the second power chiplet is configured to select a second set of VRCs corresponding to the first power rail based on a second register file.

12. The power management system of claim 10, wherein the first set of VRCs has a different number of VRCs from the second set of VRCs.

13. The power management system of claim 10, wherein the first set of VRCs has the same number of VRCs as the second set of VRCs, and at least one of the first set of VRCs is different from any of the second set of VRCs in a location in a corresponding chiplet.

14. An electronic device, comprising:
one or more processors powered by a plurality of rail voltages;
a plurality of power rails configured to provide a plurality of rail voltages;
a plurality of power chiplets coupled to the plurality of power rails, wherein each power chiplet includes a plurality of respective voltage regulator cells (VRCs), and each of the plurality of respective VRCs is configured to output a respective programmable rail voltage to a respective one of the plurality of power rails;
a power broadcast interface coupled to the plurality of power chiplets, wherein the power broadcast interface is configured to broadcast a power control command to the plurality of power chiplets and the power control command includes at least a rail identifier identifying a first power rail;
wherein each of a subset of power chiplets is configured to decode the power control command, and select a respective set of VRCs among the plurality of respective VRCs based on the rail identifier to provide power to the first power rail.

15. The electronic device of claim 14, wherein the plurality of power chiplets further include at least one remaining power chiplet that is distinct from the subset of power chiplets, and the at least one remaining power chiplet does not include any VRCs configured to provide power to the first power rail, and is configured to provide no power to the first power rail.

16. The electronic device of claim 15, wherein the at least one remaining power chiplet is configured to receive and decode the power control command and determine that none of the plurality of respective VRCs corresponds to the rail identifier.

17. The electronic device of claim 14, wherein the power broadcast interface is configured to broadcast the power control command to the plurality of power chiplets according to a predefined serial communication protocol, and the power control command follows a predefined data format.

18. The electronic device of claim 14, wherein the electronic device is integrated with one or more processors to be powered by the plurality of rail voltages in a system on a chip (SOC).

19. A method, comprising:
at a power management system including a plurality of power chiplets electrically coupled to a plurality of power rails:
receiving a power control command by each of the plurality of power chiplets, wherein the power control command includes at least a rail identifier identifying a first power rail; and
at each of a subset of power chiplets, wherein each power chiplet includes a plurality of respective voltage regulator cells (VRCs):
decoding the power control command;
selecting a respective set of VRCs among the plurality of respective VRCs based on the rail identifier; and
outputting, by each of the plurality of respective VRCs, a respective programmable rail voltage to a respective one of the plurality of power rails, including providing power to the first power rail via the respective set of VRCs.

20. The method of claim 19, wherein the power control command further includes an operation identifier and an operation parameter, and each of the subset of power chiplets is configured to power the first power rail using a first power operation identified by the operation identifier based on the operation parameter.
